(19) United States
(12) Patent Application Publication
(10) Pub. No.: US 2026/0271267 A1
(43) Pub. Date: Sep. 10, 2026

(54) SEMICONDUCTOR DEVICE

(71) Applicant: Samsung Electronics Co., Ltd., Suwon-si (KR)

(72) Inventors: Hyunwoo Bang, Suwon-si (KR); Taeyang Park, Suwon-si (KR); Hyejin Kwon, Suwon-si (KR); Youngjoon Kim, Suwon-si (KR); Sunmi Ahn, Suwon-si (KR)

(21) Appl. No.: 19/330,318

(22) Filed: Sep. 16, 2025

(30) Foreign Application Priority Data
Mar. 4, 2025 (KR) 10-2025-0027766

(51) Int. Cl. H10B 12/00

(52) U.S. Cl. CPC H10B 12/315; H10B 12/05

(57) ABSTRACT

A semiconductor device includes a substrate including a cell active region and a boundary region; a bit line extending along a first direction parallel to a top surface of the substrate; a semiconductor pattern vertically extending to the top surface of the substrate; a back gate electrode extending along a second direction intersecting the first direction; and a gate electrode spaced apart from the back gate electrode in the first direction with the semiconductor pattern therebetween. The semiconductor pattern comprises a first outer wall extending in the second direction adjacent to the back gate electrode; a second outer wall opposite to the first outer wall in the first direction; and a first side wall connecting the first outer wall and the second outer wall. An angle between the first side wall and the first outer wall is in a range from 40° to 80°.

### CROSS-REFERENCE TO RELATED APPLICATIONS

This U.S. non-provisional patent application claims priority under 35 U.S.C. § 119 to Korean Patent Application No. 10-2025-0027766, filed on Mar. 4, 2025, in the Korean Intellectual Property Office, the entire contents of which are hereby incorporated by reference.

### BACKGROUND

Semiconductor devices are in the spotlight as an important factor in the electronics industry due to their characteristics such as miniaturization, multi-functionalization, and/or low manufacturing cost. Semiconductor devices may be categorized as a semiconductor memory device that stores logic data, a semiconductor logic device that arithmetically processes logic data, a hybrid semiconductor device that includes a memory element and a logic element, and the like.

In recent years, with the increase in speed and the decrease in power consumption of electronic devices, it is advantageous for a semiconductor device incorporated therein to have a high operating speed and/or a low operating voltage. In order to satisfy these characteristics, semiconductor devices are becoming more highly integrated. Therefore, many studies have been conducted to improve the degree of integration of semiconductor devices.

### SUMMARY

Some implementations according to the present disclosure provide semiconductor devices with improved reliability and productivity, and methods of manufacturing the same.

According to some implementations of the present disclosure, a semiconductor device may include a substrate including a cell active region and a boundary region; a bit line extending along a first direction parallel to a top surface of the substrate; a semiconductor pattern extending along a direction perpendicular to the top surface of the substrate and disposed on the bit line; a back gate electrode extending along a second direction parallel to the top surface of the substrate and intersecting the first direction; and a gate electrode spaced apart from the back gate electrode in the first direction with the semiconductor pattern therebetween, wherein the semiconductor pattern comprises: a first outer wall extending in the second direction adjacent to the back gate electrode; a second outer wall opposite to the first outer wall in the first direction; and a first side wall connecting the first outer wall and the second outer wall, wherein an angle between the first side wall and the first outer wall is 40° to 80°.

According to some implementations of the present disclosure, a semiconductor device may include a substrate including a cell active region and a boundary region; a bit line extending along a first direction parallel to a top surface of the substrate; a semiconductor pattern extending along a direction perpendicular to the top surface of the substrate and disposed on the bit line; a back gate electrode extending along a second direction parallel to the top surface of the substrate and intersecting the first direction; and a gate electrode spaced apart from the back gate electrode in the first direction with the semiconductor pattern therebetween, wherein the cell active region includes a memory cell, the boundary region surrounds the cell active region and connects the cell active region and a sense amplifier, and a top surface of the semiconductor pattern of the cell active region is at the same level as a top surface of the semiconductor pattern of the boundary region.

According to some implementations of the present disclosure, a semiconductor device may include a substrate including a cell active region and a boundary region; a bit line extending along a first direction parallel to a top surface of the substrate; a semiconductor pattern extending along a direction perpendicular to the top surface of the substrate and disposed on the bit line; a back gate electrode extending along a second direction parallel to the top surface of the substrate and intersecting the first direction; a gate electrode spaced apart from the back gate electrode in the first direction with the semiconductor pattern therebetween; a gate insulating pattern between the semiconductor pattern and the gate electrode; and a back gate insulation pattern between the semiconductor pattern and the back gate electrode, wherein the semiconductor pattern comprises: a first outer wall extending in the second direction adjacent to the back gate electrode; a second outer wall opposite to the first outer wall in the first direction; and a first side wall connecting the first outer wall and the second outer wall, wherein a length of the first outer wall is greater than a length of the second outer wall and wherein a ratio of a maximum width of the semiconductor pattern in the first direction to a length of the second outer wall is in a range from 0.5 to 0.8.

According to some implementations of the present disclosure, a method for manufacturing a semiconductor device may include forming preliminary semiconductor patterns and a preliminary back gate structure between the preliminary semiconductor patterns on a substrate, the preliminary back gate structure including a preliminary back gate insulating pattern and a first preliminary back gate capping pattern; forming an etch spacer covering a side wall of a preliminary back gate insulating pattern on the preliminary semiconductor patterns; forming a poly insulating layer covering a side wall of the etch spacer on the preliminary semiconductor patterns; and forming a first mask pattern on the etch spacer, the poly insulating layer, and the preliminary back gate insulating pattern, wherein the etch spacer includes a material having an etching selectivity with respect to each of the poly insulating layer and the preliminary back gate insulating pattern.

According to some implementations, the method for manufacturing a semiconductor device may include that the etch spacer includes titanium nitride.

According to some implementations, the method for manufacturing a semiconductor device may include performing an etching process using the first mask pattern as a mask; removing, by the etching process, the etch spacer and the poly insulating layer exposed by the first mask pattern.

According to some implementations, the method for manufacturing a semiconductor device may include reducing a height of each of the preliminary back gate insulating pattern and the first preliminary back gate capping pattern by the etching process.

According to some implementations, the method for manufacturing a semiconductor device may include that a portion of the etch spacer adjacent to the preliminary back gate insulating pattern remains without being etched.

According to some implementations, the method for manufacturing a semiconductor device may include etching the preliminary semiconductor patterns through an etching process using the etch spacer as a mask to form semiconductor patterns.

According to some implementations, the method of manufacturing a semiconductor device may include forming a pad pattern between the preliminary semiconductor patterns and the etch spacer.

According to some implementations, the method of manufacturing a semiconductor device may include removing the etch spacer and the pad pattern.

According to some implementations, the method for manufacturing a semiconductor device may include that the semiconductor patterns include a first outer wall adjacent to the back gate electrode and extending in the second direction; a second outer wall opposite to the first outer wall in the first direction; and a first side wall connecting the first outer wall and the second outer wall, wherein an angle between the first side wall and the first outer wall is 40° to 80°.

According to some implementations, the method for manufacturing a semiconductor device may include that a length of the first outer wall in the second direction is greater than a length of the second outer wall in the second direction.

### BRIEF DESCRIPTION OF THE DRAWINGS

FIG. 1 is a block diagram illustrating an example of a semiconductor device.

FIGS. 2 and 3 are perspective diagrammatic views schematically illustrating examples of semiconductor devices.

FIG. 4 is a plan view of an example of a semiconductor device.

FIG. 5 is an enlarged view of an example of portion P of FIG. 4.

FIGS. 6A, 6B, and 6C are enlarged views of examples of portion M of FIG. 5.

FIG. 7A is a cross-sectional view taken along line A-A′ in FIG. 6A.

FIG. 7B is a cross-sectional view taken along line B-B′ in FIG. 6A.

FIG. 7C is a cross-sectional view taken along line C-C′ in FIG. 6A.

FIG. 7D is a cross-sectional view taken along line D-D′ in FIG. 6A.

FIGS. 8A to 18C are diagrams illustrating an example of a method of manufacturing a semiconductor device.

FIGS. 19A and 19B are diagrams illustrating an example of a method of manufacturing a semiconductor device.

FIGS. 20A to 20D are diagrams illustrating an example of a method of manufacturing a semiconductor device.

FIGS. 21A to 21F are diagrams illustrating an example of a method of manufacturing a semiconductor device.

### DETAILED DESCRIPTION

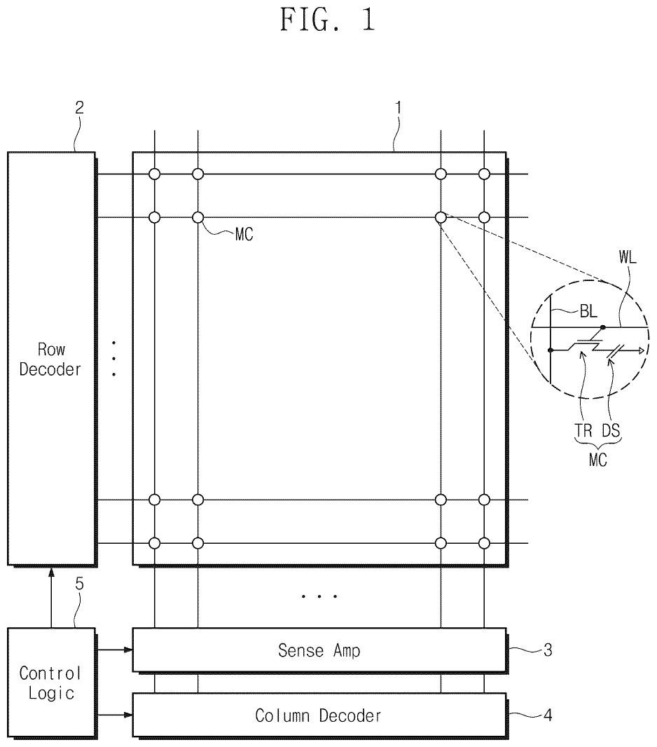

FIG. 1 is a block diagram illustrating an example of a semiconductor device according to some implementations of the present disclosure.

Referring to FIG. 1, a semiconductor device may include a memory cell array 1, a row decoder 2, a sense amplifier 3, a column decoder 4, and a control logic 5.

The memory cell array 1 may include a plurality of memory cells MC, which are two-dimensionally or three-dimensionally arranged. Each of the memory cells MC may be connected between a word line WL and a bit line BL that intersect with each other. Each of the memory cells MC may include a selection element TR and a data storage device DS. The selection element TR and the data storage device DS may be electrically connected to each other. The selection element TR may be connected to both the word line WL and the bit line BL. In other words, the selection element TR may be provided at an intersection of the word line WL and the bit line BL.

The selection element TR may include a field-effect transistor. The data storage device DS may include a capacitor, a magnetic tunnel junction pattern, or a variable resistor. For example, a gate terminal of a transistor that is the selection element TR may be connected to the word line WL, and the source/drain terminals of the transistor may be respectively connected to a bit line BL and a data storage device DS.

The row decoder 2 may decode an externally input address to select one of the word lines WL of the memory cell array 1. The address decoded by the row decoder 2 may be provided to a row driver, and the row driver may provide respective predetermined voltages to the selected word line WL and the unselected word lines WL in response to control of the control circuits.

The sense amplifier 3 may sense, amplify, and output a difference in voltage between the selected bit line BL, which is selected based on address decoded by the column decoder 4, and a reference bit line.

The column decoder 4 may provide a data transmission path between the sense amplifier 3 and an external device (e.g., a memory controller). The column decoder 4 may decode an externally input address to select one of the bit lines BL. The control logic 5 may generate a control signal that controls an operation of writing or reading data to or from the memory cell array 1.

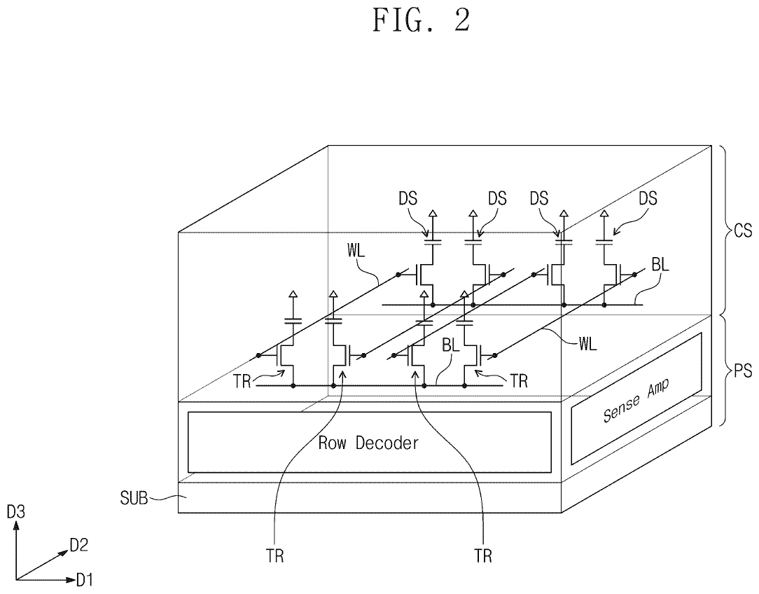

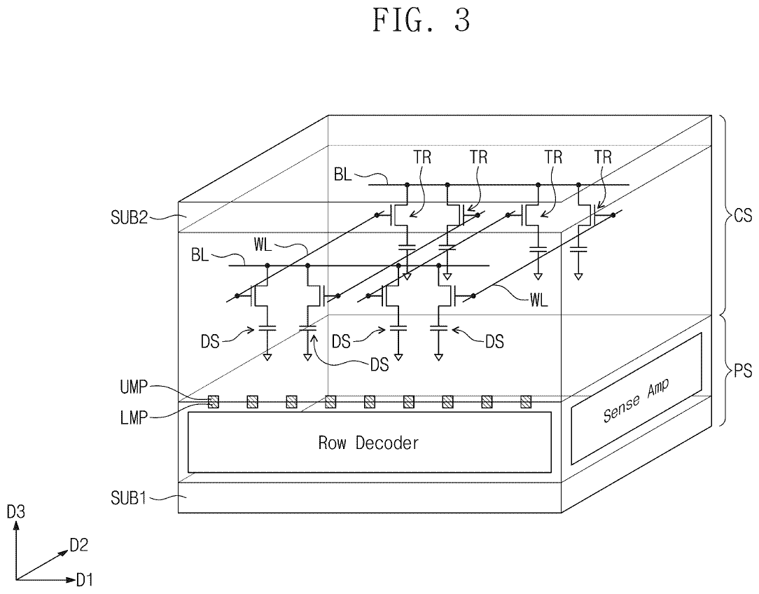

FIGS. 2 and 3 are perspective diagrammatic views schematically illustrating examples of a semiconductor device.

Referring to FIGS. 2 and 3, the semiconductor device may include a peripheral circuit structure PS on a substrate SUB1 and a cell array structure CS connected to the peripheral circuit structure PS. The substrate SUB1 may have a plate shape extending along a plane defined by a first direction D1 and a second direction D2. The first direction D1 and the second direction D2 are respectively parallel to the top surface of the substrate SUB and may intersect with each other. The first and second directions D1 and D2 may be perpendicular to each other. A third direction D3 may be perpendicular to the top surface of the substrate SUB and may intersect the first direction D1 and the second direction D2.

The peripheral circuit structure PS may include a core and peripheral circuits formed on the substrate SUB. The core and peripheral circuits may include row and column decoders 2 and 4, sense amplifier 3, and control logic 5 described with reference to FIG. 1.

The cell array structure CS may include the memory cell array 1 of FIG. 1 that includes two-dimensionally or three-dimensionally arranged memory cells MC of FIG. 1. For example, the selection element TR of each of the memory cells MC of FIG. 1 may include a vertical channel transistor VCT. The vertical channel transistor may include a channel whose lengthwise direction is the third direction D3.

Referring to FIG. 2, the peripheral circuit structure PS may be provided on the substrate SUB. The cell array structure CS may be provided on the peripheral circuit structure PS. The peripheral circuit structure PS may be connected to the cell array structure CS through a contact.

Referring to FIG. 3, a semiconductor device may include a chip-to-chip (C2C) structure. The peripheral circuit structure PS may be provided on the substrate SUB1. First metal pads LMP may be provided on a top portion of the peripheral circuit structure PS. The first metal pads LMP may be electrically connected to the core and peripheral circuits. The first metal pads LMP in the peripheral circuit structure PS may be bonded to second metal pads UMP of the cell array structure CS to be described later. Accordingly, the peripheral circuit structure PS and the cell array structure CS may be bonded.

The cell array structure CS may be provided on a carrier substrate SUB2. The second metal pads UMP may be provided on a lower portion of the cell array structure CS. The second metal pads UMP may be electrically connected to the memory cell array 1 (shown in FIG. 1).

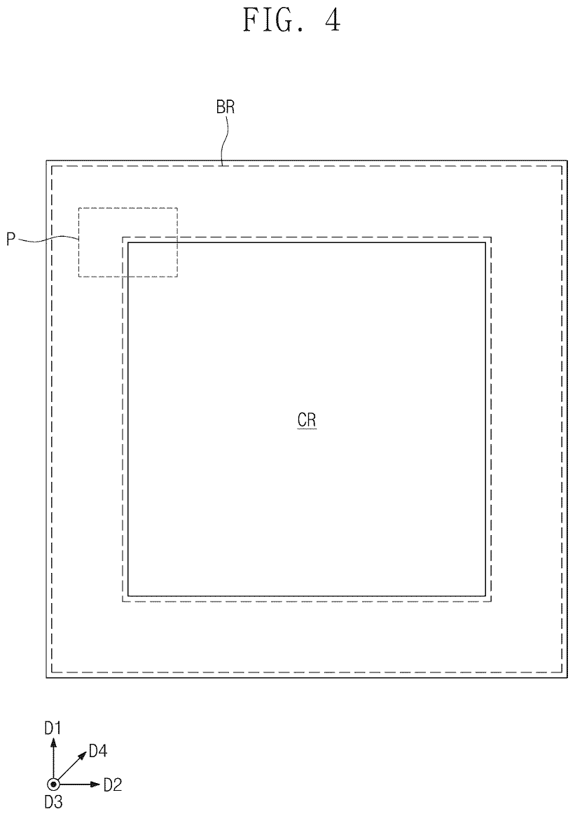

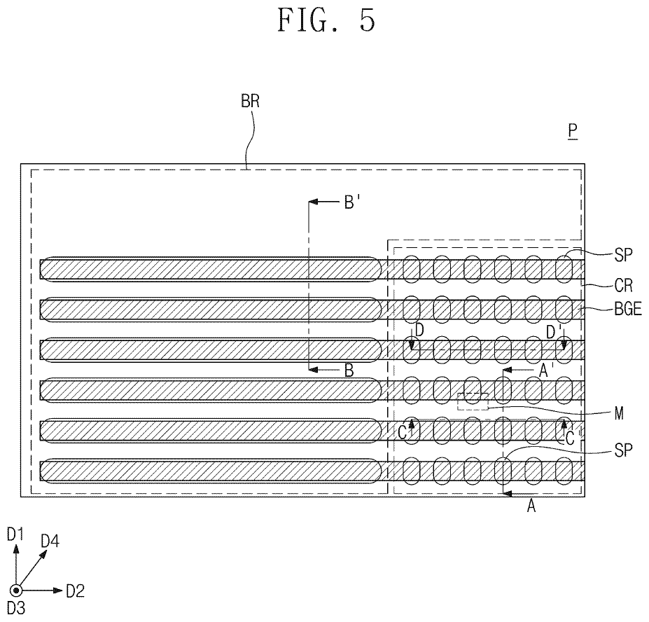

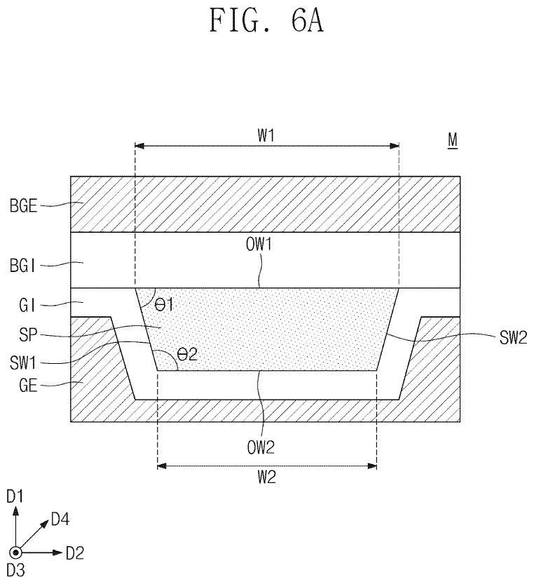

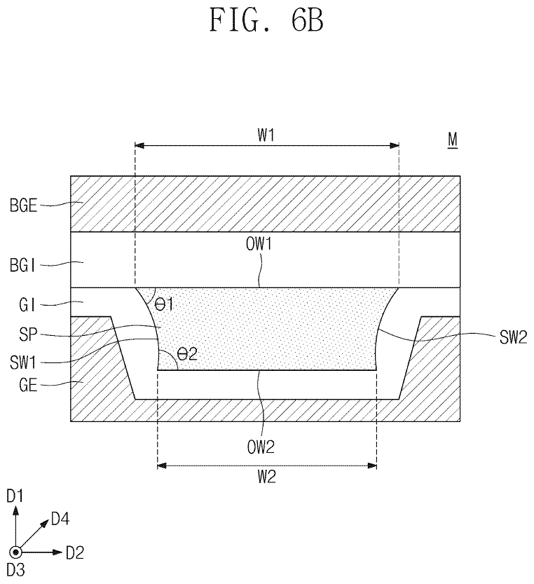

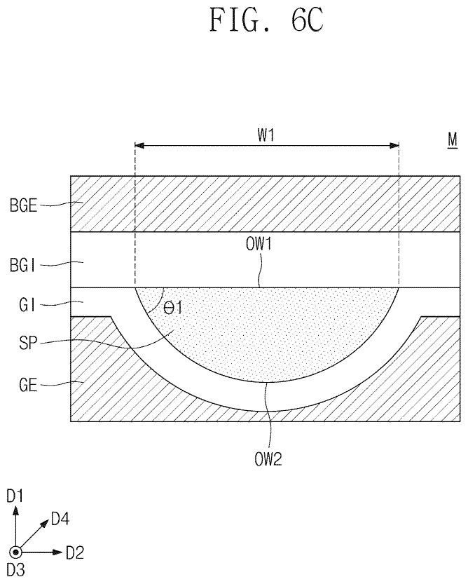

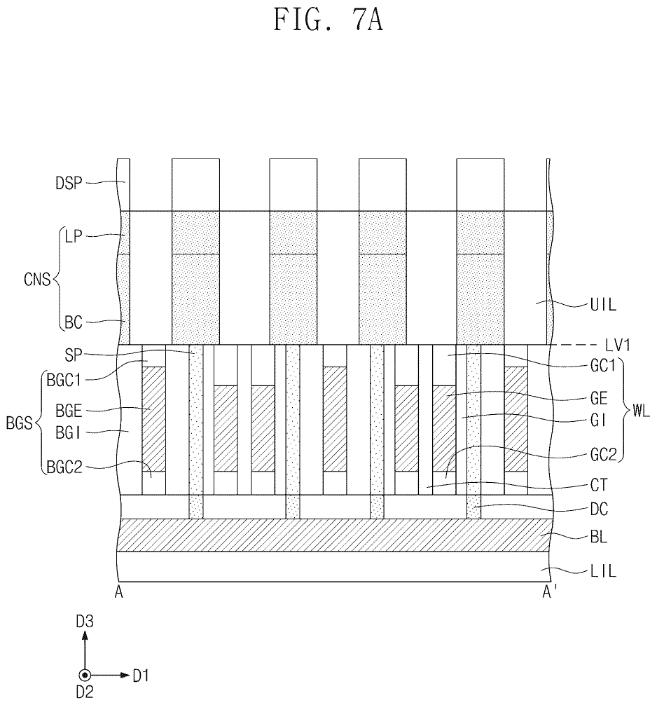

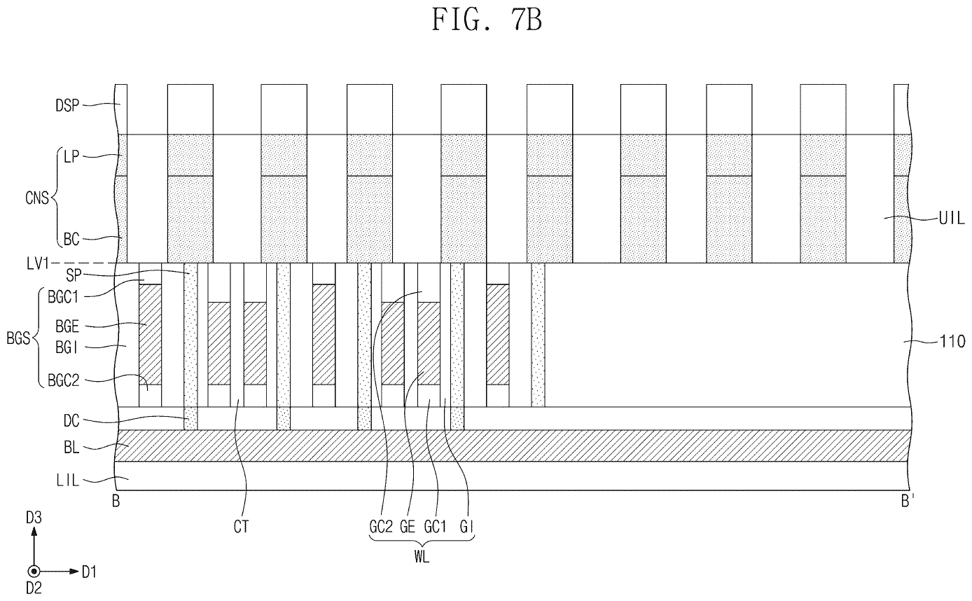

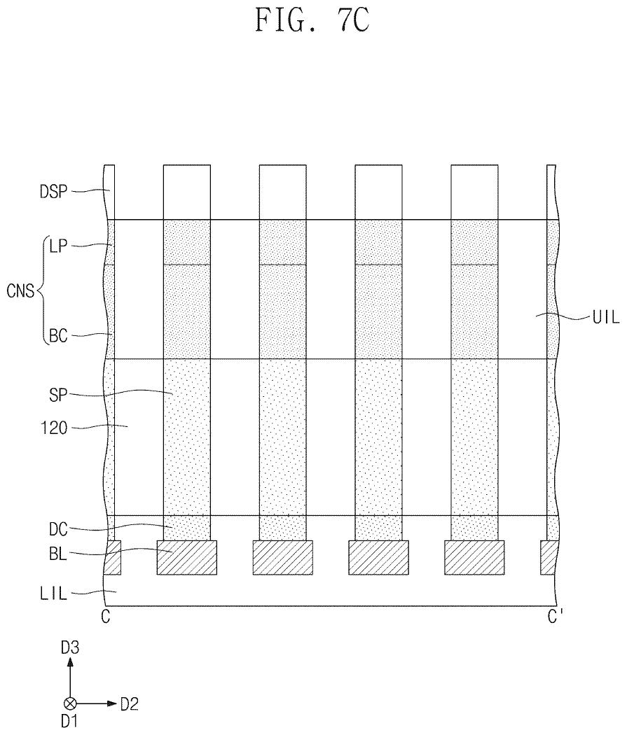

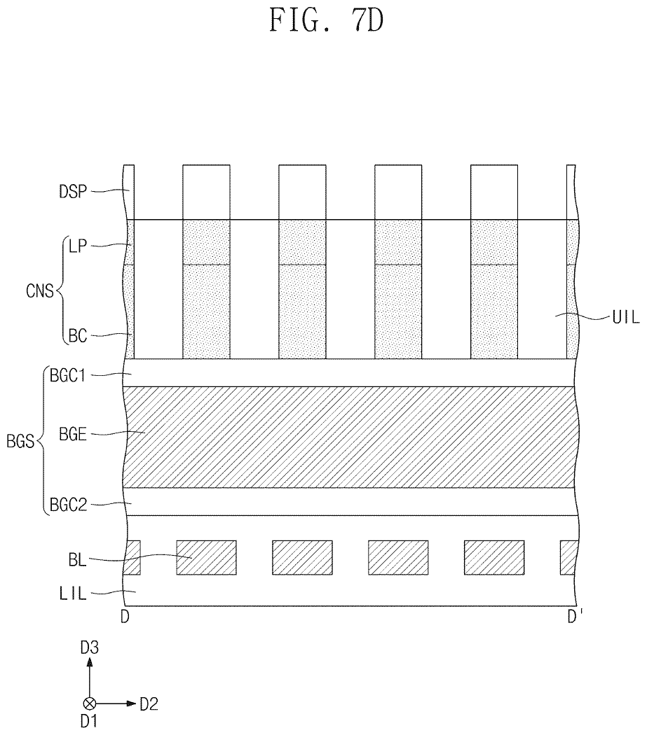

FIG. 4 is a plan view of an example of a semiconductor device. FIG. 5 is an enlarged view of portion P of FIG. 4. FIGS. 6A to 6C are enlarged views of examples of portion M of FIG. 5. FIGS. 7A to 7D are cross-sectional views taken along lines A-A′, B-B′, C-C′, and D-D′ of FIG. 6A, respectively.

Referring first to FIG. 4 and 7A to 7D, the cell array structure CS with reference to FIGS. 2 and 3 will be described.

The semiconductor device may include a lower insulating layer LIL. The lower insulating layer LIL may include an insulating material. For example, the lower insulating layer LIL may be provided on the lower portion of the cell array structure CS described with reference to FIG. 2. In this case, the lower insulating layer LIL may be adjacent to and in contact with the peripheral circuit structure PS with reference to FIG. 2. In addition, the peripheral circuit structure PS described with reference to FIG. 2 may be interposed between the substrate SUB1 and the lower insulating layer LIL with reference to FIG. 2. In addition, the lower insulating layer LIL may include wirings connected to the core and peripheral circuits of the peripheral circuit structure PS described with reference to FIG. 2.

In some implementations, the cell array structure (CS in FIG. 2) of the semiconductor device is flipped (inverted), so that the lower insulating layer LIL may be provided in an upper portion of the cell array structure CS described with reference to FIG. 3. In this case, the lower insulating layer LIL may be adjacent to and in contact with the carrier substrate SUB2 described with reference to FIG. 3. A plan view and a cross-sectional view of the cell array structure (CS in FIG. 2) of the semiconductor device in an un-inverted state are shown, and the semiconductor device will be described with reference thereto, but the cell array structure is not limited thereto.

The bit line BL may be provided in the lower insulating layer LIL. The bit line BL may extend along the first direction D1 in the lower insulating layer LIL. The bit line BL may include a conductive material. For example, the bit line BL may include at least one of a doped semiconductor material (e.g., doped silicon, doped germanium, etc.), a metal material (e. g., Ti, Mo, W, Cu, Al, Ta, Ru, Ir, Co, etc.) a metal silicide (e. g, a silicide of Ti, Mo, W, Cu, A1, Ta, Ru, Ir, Co, etc.) or a metal nitride (e.g., a nitride of Ti, Mo, W, Cu, Al, Ta, Ru, Ir, Co, etc.). The bit line BL may be a single layer or a composite layer. A plurality of bit lines BL may be provided. The bit lines BL may be spaced apart from each other along the second direction D2.

A bit line contact DC may be provided in the lower insulating layer LIL. The bit line contact DC may be provided on the bit line BL. The bit line contact DC may be interposed between the semiconductor pattern SP and the bit line BL, which will be described later. Accordingly, the bit line BL may be connected to the semiconductor pattern SP through the bit line contact DC. The bit line contact DC may include a conductive material. For example, the bit line contact DC may include doped silicon. A plurality of bit line contacts DC may be provided. The bit line contacts DC may be spaced apart from each other along the first direction D1 on one bit line BL.

The semiconductor pattern SP may be provided on the bit line BL. For example, the semiconductor pattern SP may be provided on a top surface of the bit line contact DC. The semiconductor pattern SP may extend along the third direction D3 on the bit line BL. A plurality of semiconductor patterns SP may be provided. The semiconductor patterns SP may be spaced apart from each other along the first direction D1 on one bit line BL. The semiconductor patterns SP may be spaced apart from each other along the second direction D2.

The semiconductor pattern SP may include a semiconductor material. For example, the semiconductor pattern SP may include at least one of silicon (e.g., single crystal silicon), germanium, or silicon-germanium. For example, the semiconductor pattern SP may include an oxide semiconductor. The oxide semiconductor may include, at least one of InGaZnO, InGaSiO, InSnZnO, InZnO, ZnO, ZnSnO, ZnON, ZrZnSnO, SnO, HfInZnO, GaZnSnO, AlZnSnO, YbGaZnO, or InGaO, but is not limited thereto. For example, the semiconductor pattern SP may include Indium Gallium Zinc Oxide (IGZO). For example, the semiconductor pattern SP may include a two-dimensional semiconductor material. For example, the two-dimensional semiconductor material may include graphene, carbon nanotubes, or a combination thereof.

A word line WL may be provided on a side wall of the semiconductor pattern SP. The word line WL may be interposed between the semiconductor patterns SP adjacent to each other in the first direction D1. The word line WL may extend along the second direction D2. A plurality of word lines WL may be provided. The word lines WL may be spaced apart from each other along the first direction D1. For example, a pair of word lines WL adjacent to each other in the first direction D1 may be interposed between semiconductor patterns SP adjacent to each other in the first direction D1. For example, a pair of word lines WL adjacent to each other in the first direction D1 may be spaced apart from each other with a cutting pattern CT, which will be described later, interposed therebetween.

The word line WL may include a gate electrode GE extending along the second direction D2 and the third direction D3, a gate insulating pattern GI between the semiconductor pattern SP and the gate electrode GE, a first gate capping pattern GC1 on a bottom surface of the gate electrode GE, and a second gate capping pattern GC2 on a top surface of the gate electrode GE. The gate electrode GE may include a conductive material. For example, the gate electrode GE may include at least one of a metal material (e.g., Ti, Mo, W, Cu, Al, Ta, Ru, Ir, Co, etc.), a metal silicide (e.g., a silicide of Ti, Mo, W, Cu, A1, Ta, Ru, Ir, Co, etc.), or a metal nitride (e.g., a nitride of Ti, Mo, W, Cu. Al, Ta, Ir, Co, etc.). For example, the gate insulating pattern GI may include at least one of silicon oxide or a high dielectric material. Herein, a high dielectric material is defined as a material having a dielectric constant higher than that of silicon oxide. Each of the first gate capping pattern GC1 and the second gate capping pattern GC2 may include an insulating material. For example, the first gate capping pattern GC1 and the second gate capping pattern GC2 may include at least one of silicon oxide or silicon nitride.

The cutting pattern CT may be interposed between the word lines WL adjacent to each other in the first direction D1, and may space the word lines WL apart. The cutting pattern CT may extend along the third direction D3. For example, the cutting pattern CT may include an insulating material.

A back gate structure BGS may be provided on a side wall of the semiconductor pattern SP. The back gate structure BGS may be interposed between the semiconductor patterns SP adjacent to each other in the first direction D1. The back gate structure BGS and the word line WL may be spaced apart from each other in the first direction D1 with the semiconductor pattern SP interposed therebetween. The back gate structure BGS may extend along the second direction D2 between the semiconductor patterns SP adjacent to each other in the first direction D1. A plurality of back gate structures BGS may be provided. The back gate structures BGS may be spaced apart from each other along the first direction D1.

When the back gate structure BGS is provided, the threshold voltage of the transistor including the semiconductor pattern SP may be adjusted by the voltage applied to the back gate structure BGS. Accordingly, adjusting the threshold voltage through the back gate structure BGS may be easier than adjusting the threshold voltage by injecting dopants into the semiconductor pattern SP. By adjusting the threshold voltage through the back gate structure BGS, the transistor can be prevented from being unnecessarily Turn-on.

The back gate structure BGS may include a back gate electrode BGE, a first back gate capping pattern BGC1 on a top surface of the back gate electrode BGE, a second back gate capping pattern BGC2 on a bottom surface of the back gate electrode BGE, and a back gate insulating pattern BGI covering a side wall thereof. For example, the back gate electrode BGE may include at least one of a metal material (e.g., Ti, Mo, W, Cu, Al, Ta, Ru, Ir, Co, etc.), a metal silicide (e.g., a silicide of Ti, Mo, W, Cu, Al. Ta, Ru, Ir, Co, etc.), or a metal nitride (e.g., a nitride of Ti, Mo, W, Cu. Al, Ta, Ro, Ir, Co, etc.). For example, the first and second back gate capping patterns BGC1 and BGC2 may include an insulating material. In some implementations, the back gate insulating pattern BGI may include at least one of silicon oxide or a high dielectric material.

An interlayer insulating layer 120 (shown in FIG. 7C) may be provided on the lower insulating layer LIL. The interlayer insulating layer 120 may be interposed between the semiconductor patterns SP adjacent to each other in the second direction D2. For example, the interlayer insulating layer 120 may include an insulating material.

A connection structure CNS may be provided on the semiconductor pattern SP. The connection structure CNS may include a storage node contact BC and a landing pad LP. The storage node contact BC may be provided on a top surface of the semiconductor pattern SP. The storage node contact BC may include a conductive material. For example, the storage node contact BC may include doped silicon. A plurality of storage node contacts BC may be provided. The storage node contacts BC may be spaced apart from each other in the first direction D1 and the second direction D2.

A landing pad LP may be provided on the storage node contact BC. The storage node contact BC and the landing pad LP may vertically overlap each other. A side wall of the storage node contact BC and a side wall of the landing pad LP may be aligned. The landing pad LP may be connected to the semiconductor pattern SP through the storage node contact BC. The landing pad LP may include a conductive material. For example, the landing pad LP may include at least one of a doped semiconductor material (e.g., doped silicon, doped germanium, etc.), a metal material (e.g., Ti, Mo, W, Cu, Al, Ta, Ru, Ir, Co, etc.), metal silicide (e.g., a silicide of Ti, Mo, W, Cu, Al, Ta, Ru, Ir, Co, etc.), or a metal nitride (e.g., a nitride of Ti, Mo, W, Cu, Al, Ta, Ru, Ir, Co, etc.).

A plurality of landing pads LP may be provided. The landing pads LP may be spaced apart from each other in the first direction D1 and the second direction D2. For example, the landing pads LP may be arranged in various shapes such as a zigzag shape, a matrix shape, and a honeycomb shape in a plan view. For example, the landing pad LP may have various shapes such as a circle, an ellipse, a rectangle, a square, a rhombus, and a hexagon in a plan view.

An upper insulating layer UIL surrounding the storage node contact BC and the landing pad LP may be provided. The upper insulating layer UIL may include an insulating material. The upper insulating layer UIL may be a single layer or a composite layer. The upper insulating layer UIL may space the plurality of storage node contacts BC apart from each other. The upper insulating layer UIL may separate a plurality of landing pads LP from each other.

A data storage pattern DSP may be provided on the landing pad LP. The data storage pattern DSP may be connected to the semiconductor pattern SP through the landing pad LP and the storage node contact BC. A plurality of data storage patterns DSP may be provided. The data storage patterns DSP may be spaced apart from each other in the first direction D1 and the second direction D2. The data storage pattern DSP may correspond to the data storage device DS described with reference to FIGS. 1 to 3.

The data storage pattern DSP may be, for example, a capacitor including a lower electrode, a dielectric layer, and an upper electrode. In this case, the semiconductor device may be a dynamic random access memory (DRAM). The data storage pattern DSP may include, for example, a magnetic tunnel junction pattern. In this case, the semiconductor device may be a magnetic random access memory (MRAM). The data storage pattern DSP may include a phase change material or a variable resistance material. In this case, the semiconductor device may be a phase-change random access memory (PRAM) or a resistive random access memory (ReRAM). However, these are merely examples, and the data storage pattern DSP is not limited thereto, but rather may include various suitable structures and/or materials capable of storing data.

Hereinafter, the semiconductor pattern SP will be described in more detail with reference to FIGS. 5 to 7D.

Referring to FIGS. 5 and 6A, the semiconductor pattern SP may be interposed between the back gate electrode BGE and the gate electrode GE. A back gate insulating pattern BGI may be provided between the semiconductor pattern SP and the back gate electrode BGE. A gate insulating pattern GI may be provided between the semiconductor pattern SP and the gate electrode GE. The semiconductor pattern SP may be interposed between the back gate insulating pattern BGI and the gate insulating pattern GI. The gate insulating pattern GI may be in contact with the back gate insulating pattern BGI.

The semiconductor pattern SP may include a first outer wall OW1, a second outer wall OW2, a first side wall SW1, and a second side wall SW2. The first outer wall OW1 may be adjacent to the back gate electrode BGE and may extend parallel to the back gate electrodes BGE. For example, as shown in FIGS. 6A-6C, in the first direction D1, the first outer wall OW1 can be closer than the second outer wall OW2 to the back gate electrode BGE. For example, the first outer wall OW1 may extend in the second direction D2. The first outer wall OW1 may be in contact with the back gate insulating pattern BGI. The second outer wall OW2 may be a surface opposite to the first outer wall OW1 in the first direction D1. The second outer wall OW2 may be adjacent to the gate electrode GE and may extend in the second direction D2. For example, in the first direction D1, the second outer wall OW2 can be closer than the first outer wall OW1 to the gate electrode GE. The second outer wall OW2 may be in contact with the gate insulating pattern GI.

Each of the first side wall SW1 and the second side wall SW2 may connect the first outer wall OW1 and the second outer wall OW2. The first side wall SW1 may be a surface opposite to the second side wall SW2. The first side wall SW1 and the second side wall SW2 may be in contact with the gate insulating pattern GI. The first side wall SW1 and the second side wall SW2 may extend obliquely with respect to the first direction D1 and the second direction D2.

A first angle θ1 between the first side wall SW1 and the first outer wall OW1 may be an acute angle. For example, the first angle θ1 may be in a range from 40° and 80°. For example, the first angle θ1 may be less than 70°. A second angle θ2 between the first side wall SW1 and the second outer wall OW2 may be an obtuse angle. For example, the second angle θ2 may be in a range from 100° and 140°. For example, the second angle θ2 may be greater than 110°.

An angle between the second side wall SW2 and the first outer wall OW1 may be an acute angle. For example, the angle between the second side wall SW2 and the first outer wall OW1 may be in a range from 40° to 80°. For example, the angle between the second side wall SW2 and the first outer wall OW1 may be less than 70°. The angle formed by the second side wall SW2 and the second outer wall OW2 may be an obtuse angle. For example, an angle between the second side wall SW2 and the second outer wall OW2 may be in a range from 100° to 140°. For example, the angle between the second side wall SW2 and the second outer wall OW2 may be greater than 110°.

The first outer wall OW1 may have a first length W1 in the second direction D2. The second outer wall OW2 may have a second length W2 in the second direction D2. The first length W1 may be greater than the second length W2. For example, a ratio of the first length W1 to the second length W2 may be in a range from 1.4 to 1.7.

A maximum (greatest) width of the semiconductor pattern SP in the second direction D2 may be the same as the first length W1 of the first outer wall OW1. In other words, the semiconductor pattern SP may have a maximum (greatest) width in the second direction D2 at the first outer wall OW1. The width of the semiconductor pattern SP in the second direction D2 may decrease as the distance from the first outer wall OW1 increases.

A minimum width of the semiconductor pattern SP in the second direction D2 may be the same as the second length W2 of the second outer wall OW2. In other words, the semiconductor pattern SP may have a minimum width in the second direction D2 at the second outer wall OW2. The width of the semiconductor pattern SP in the second direction D2 may increase as the distance from the second outer wall OW2 increases.

The second length W2 of the second outer wall OW2 may be greater than a width of the semiconductor pattern SP in the first direction D1. For example, a ratio of the maximum (greatest) width of the semiconductor pattern SP in the first direction D1 to the second length W2 of the second outer wall OW2 may be in a range from 0.5 to 0.8.

FIGS. 6B and 6C are enlarged views, respectively, of the M portion of FIG. 5 according to other examples. For simplicity of description, description of content overlapping with the above-described content will be omitted, and differences from the above-described contents will be mainly described.

Referring to FIG. 6B, the first side wall SW1 and the second side wall SW2 may be curved surfaces that are concave toward the inside of the semiconductor pattern SP. The first side wall SW1 and the second side wall SW2 may be curved surfaces that are recessed toward the inside of the semiconductor pattern SP. The first angle θ1 may be an angle between the first side wall SW1 and the first outer wall OW1 meet. The second angle θ2 may be an angle between the first side wall SW1 and the second outer wall OW2.

Referring to FIG. 6C, the semiconductor pattern SP may have a hemispherical profile. In this case, the first and second side walls SW1 and SW2 may be omitted, and the second outer wall OW2 may be directly connected to the first outer wall OW1. The second outer wall OW2 may be a convex curved surface toward the gate electrode GE. In this case, the first angle θ1 may be an angle between the first outer wall OW1 and the second outer wall OW2.

FIGS. 7A, 7B, and 7C are cross-sectional views illustrating an example of a cell active region CR, and FIG. 7D is a cross-sectional view illustrating an example of a boundary region BR.

Referring to FIGS. 4, 5, and 7A to 7D, the cell active region CR may be a region including a memory cell. The cell active region CR may control the bit line BL. The boundary region BR may be adjacent to an edge region of the cell active region CR. The boundary region BR may surround the cell active region CR. Like the cell active region CR, the boundary region BR may include a bit line BL and a word line WL and may connect the bit line BL extending from the cell active region CR to the sense amplifier 3 of FIG. 1. For example, the bit line BL of the boundary region BR may be connected to the sense amplifier 3 through a contact. As another example, the boundary region BR may be a region connected to the row decoder 2 of FIG. 1. For example, the word line WL of the boundary region BR may be connected to the row decoder 2 through a contact.

Referring to FIGS. 7A to 7D, the bit line BL of the cell active region CR may extend on the boundary region BR. In the boundary region BR, a dummy insulating layer 110 may be provided on a portion of the bit line BL. The dummy insulating layer 110 may include a plurality of insulating layers. The dummy insulating layer 110 may include an insulating material. The dummy insulating layer 110 may be spaced apart from the semiconductor pattern SP and the word line WL of the boundary region BR in the first direction D1. The connection structure CNS and the data storage pattern DSP may be provided on the dummy insulating layer 110. The bit line BL of the boundary region BR may be connected to the sense amplifier 3 through a contact. The contact connected to the bit line BL may be provided in the lower insulating layer LIL.

The top surface of the semiconductor pattern SP on the cell active region CR may be located at a first level LV1. The top surface of the semiconductor pattern SP on the boundary region BR may also be located at the first level LV1. For example, the top surface of the semiconductor pattern SP on the cell active region CR and the top surface of a semiconductor pattern SP on the boundary region BR may be located at the same level. The height of the semiconductor pattern SP on the cell active region CR may be the same as the height of the semiconductor patterns SP on the boundary region BR.

On the cell active region CR, the top surface of the semiconductor pattern SP may be coplanar with a top surface of the first back gate capping pattern BGC1. On the boundary region BR, the top surface of the semiconductor pattern SP may be coplanar with the top surface of a first back gate capping pattern BGC1. Thus, the top surface of the first back gate capping pattern BGC1 of the cell active region CR may be located at the same level as the top surface of the first back gate capping pattern BGC1 on the boundary region BR.

On the cell active region CR and the boundary region BR, the height of the first back gate capping pattern BGC1 may be in a range from 150 Å to 200 Å. The height of the first gate capping pattern GC1 may be in a range from 200 Å and 300 Å. The height of the first back gate capping pattern BGC1 may be 5% to 15% of the height of the back gate structure BGS. This is because the height of the first back gate capping pattern BGC1 may be reduced and the height of the back gate electrode BGE may be increased by adjusting the height of the first back gate capping pattern BGC1 in the manufacturing method to be described later.

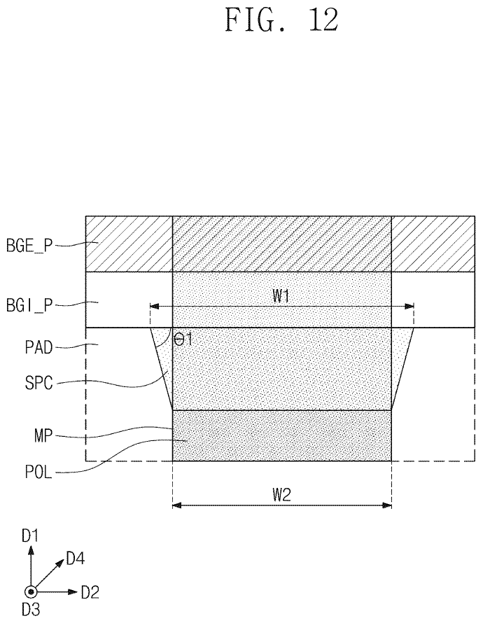

According to some implementations, an angle between the first outer wall OW1 and the first side wall SW1 adjacent to the back gate electrode BGE of the semiconductor pattern SP may be 40° to 80°. The first length W1 of the first outer wall OW1 of the semiconductor pattern SP may be greater than the second length W2 of the second outer wall OW2. This is because when the etch spacer SPC is etched to form the semiconductor pattern SP in a manufacturing method to be described later, a portion of the etch spacer SPC adjacent to the back gate insulating pattern BGE may be not etched (see FIG. 12).

In addition, in some implementations, the top surface of each of the semiconductor patterns SP on the cell active region CR and the boundary region BR may be located at the same level. That is, there may be no difference in height between the semiconductor patterns SP on the cell active region CR and the boundary region BR. The height difference between the semiconductor patterns SP on the cell active region CR and the boundary region BR may be as small as 50 Å or less. Therefore, the height of the semiconductor pattern SP can be sufficiently ensured in both the cell active region CR and the boundary region BR. Accordingly, reliability and electrical characteristics of the semiconductor device can be improved.

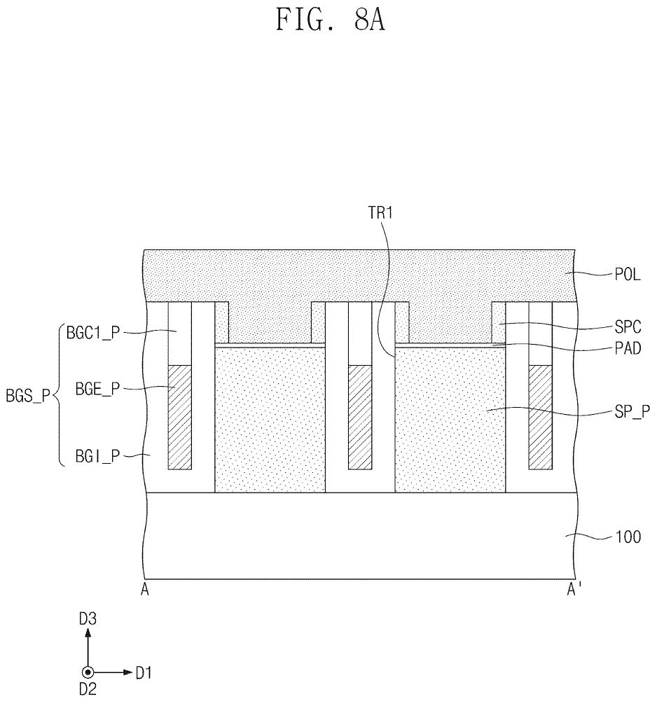

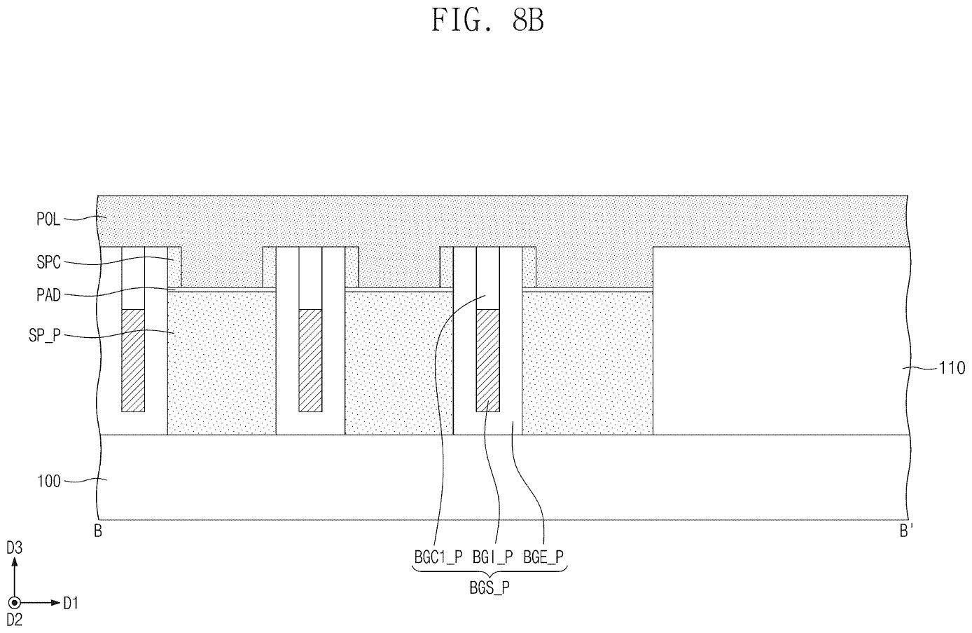

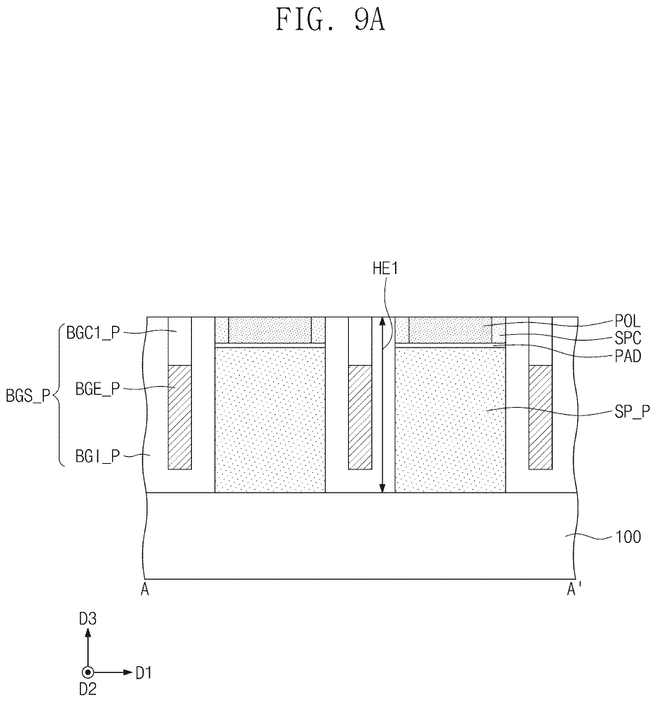

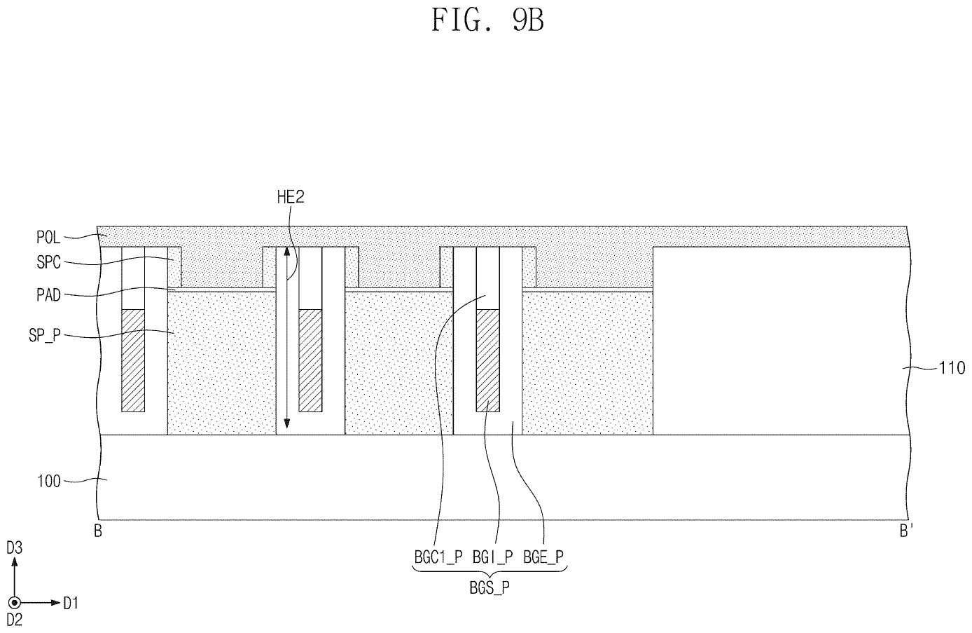

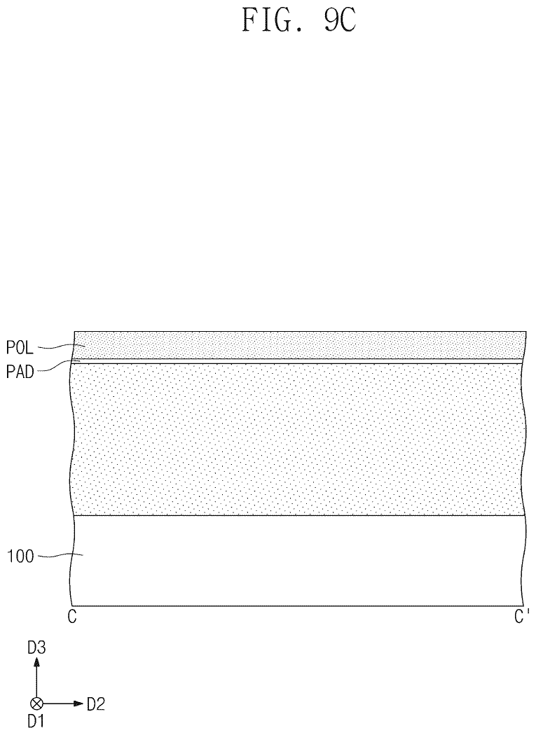

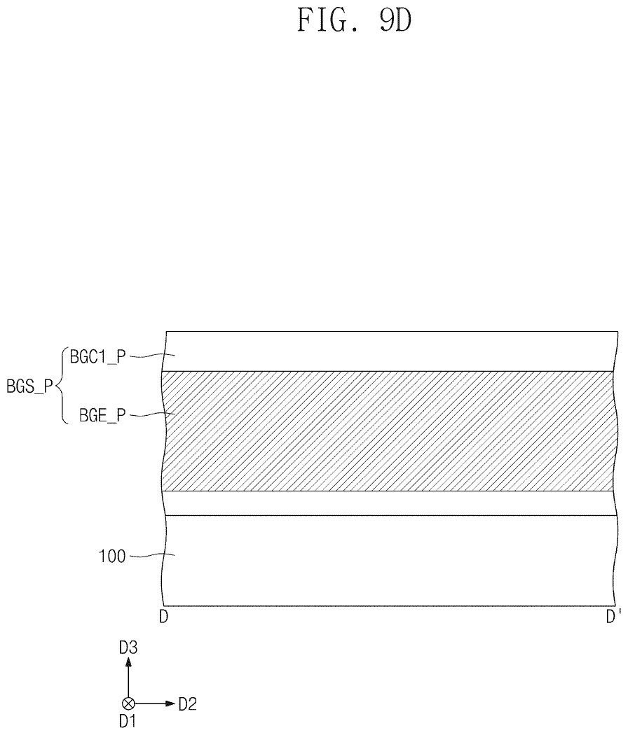

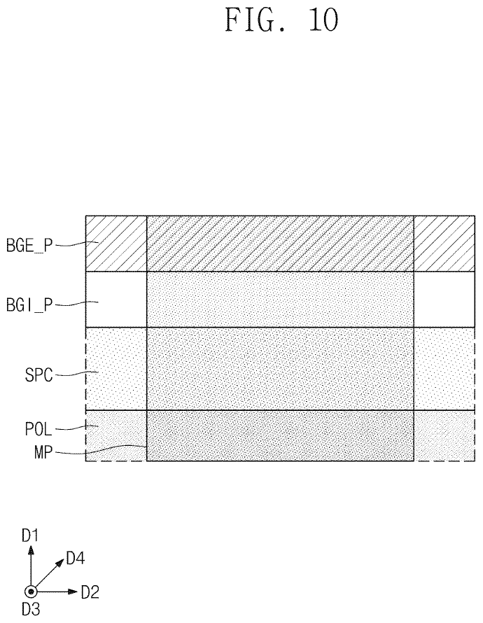

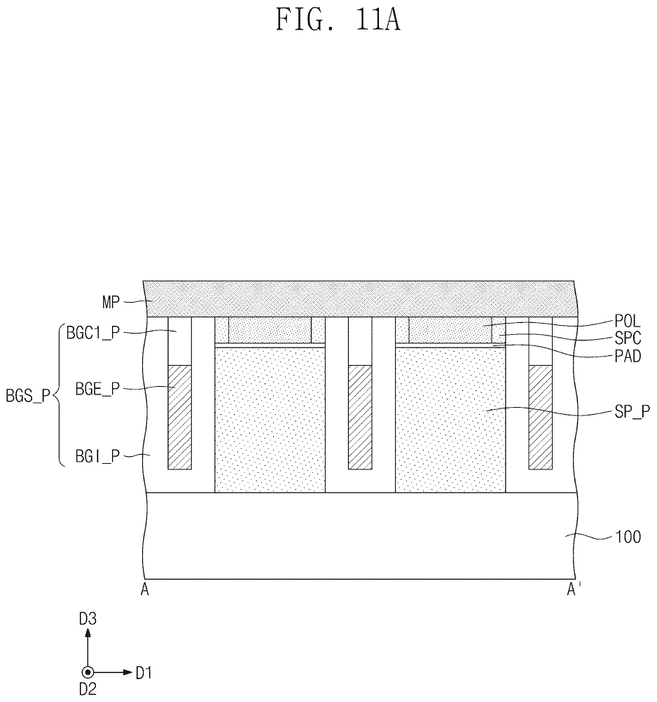

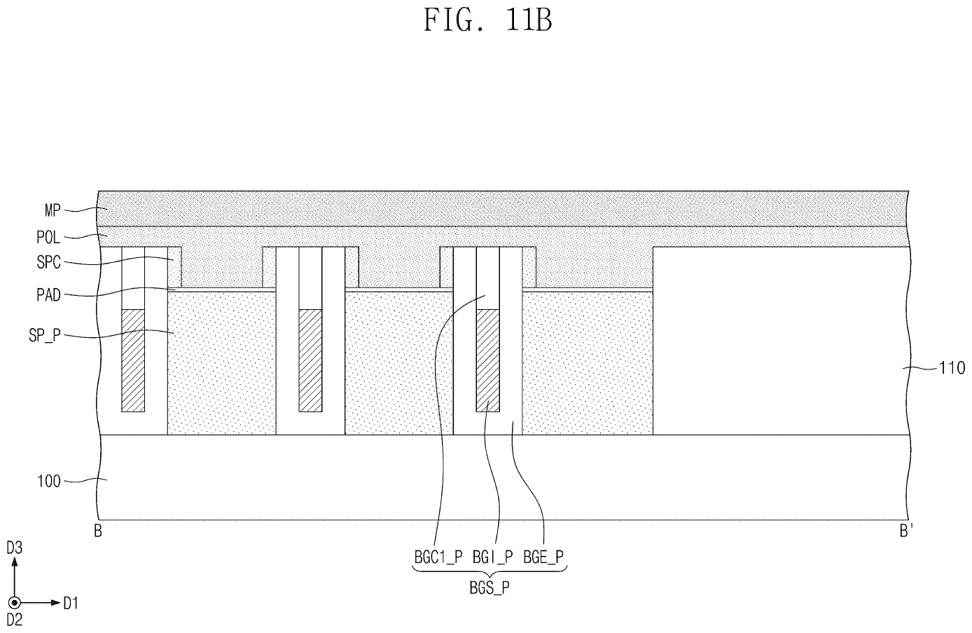

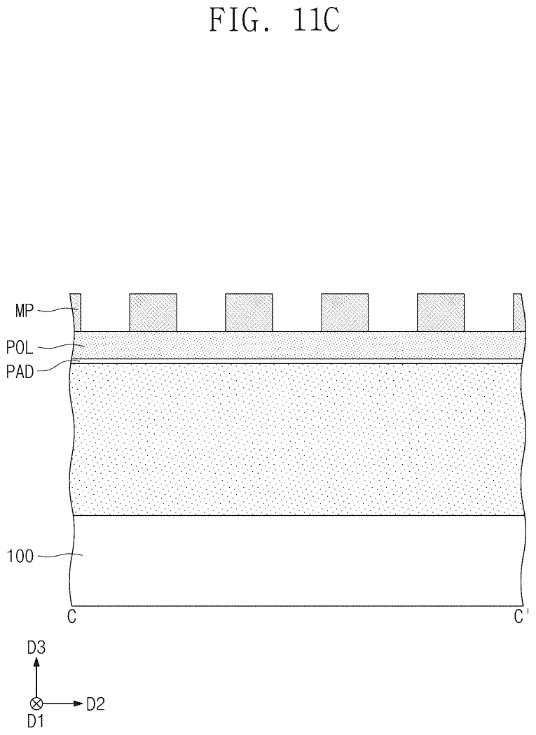

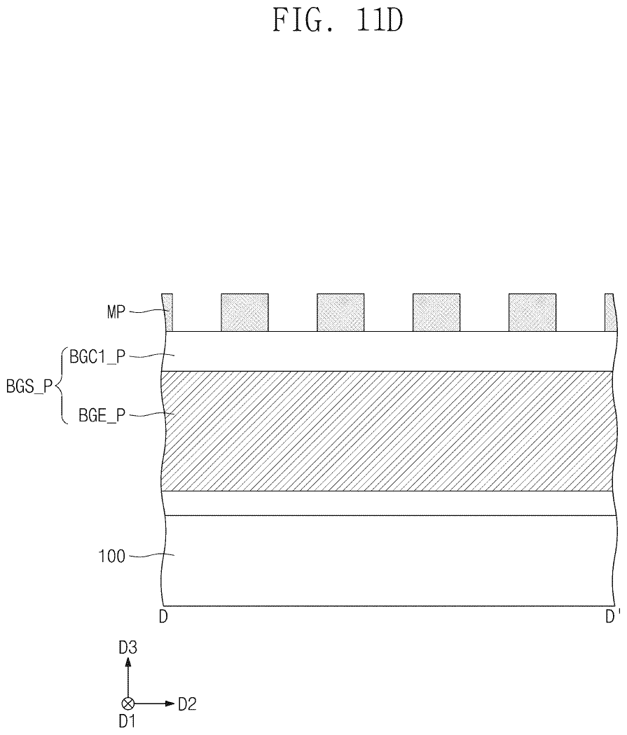

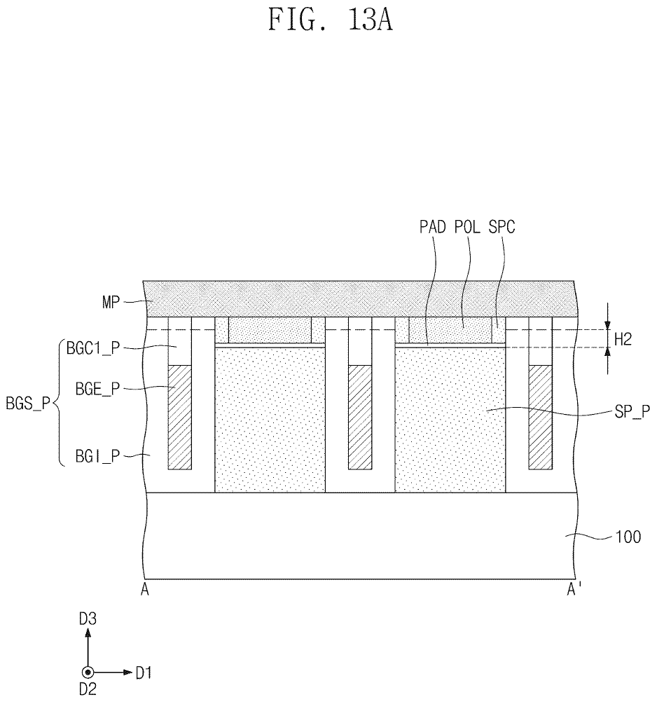

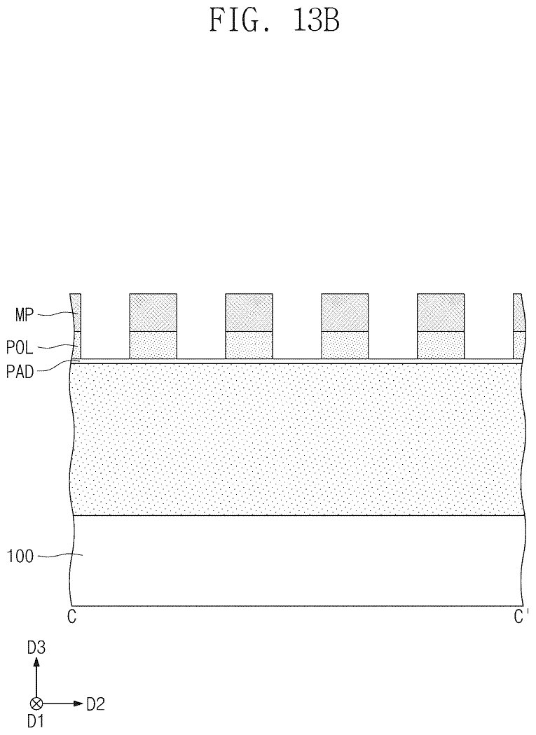

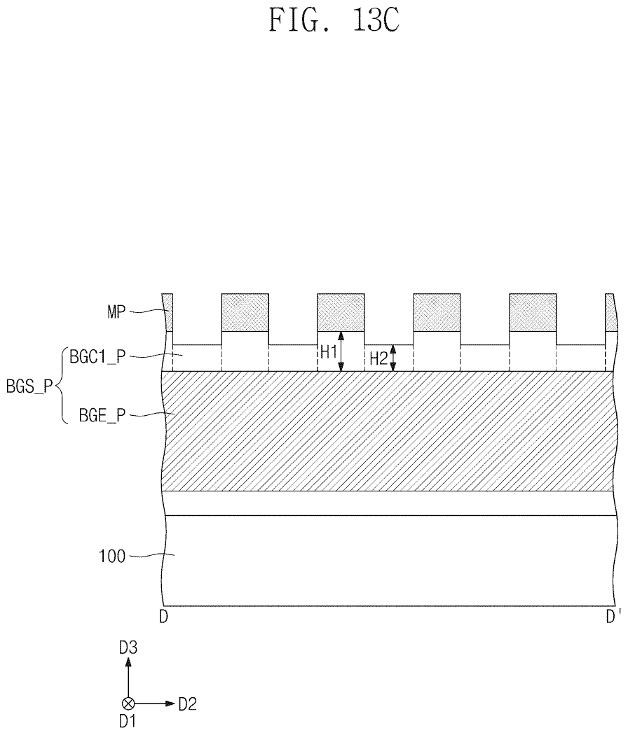

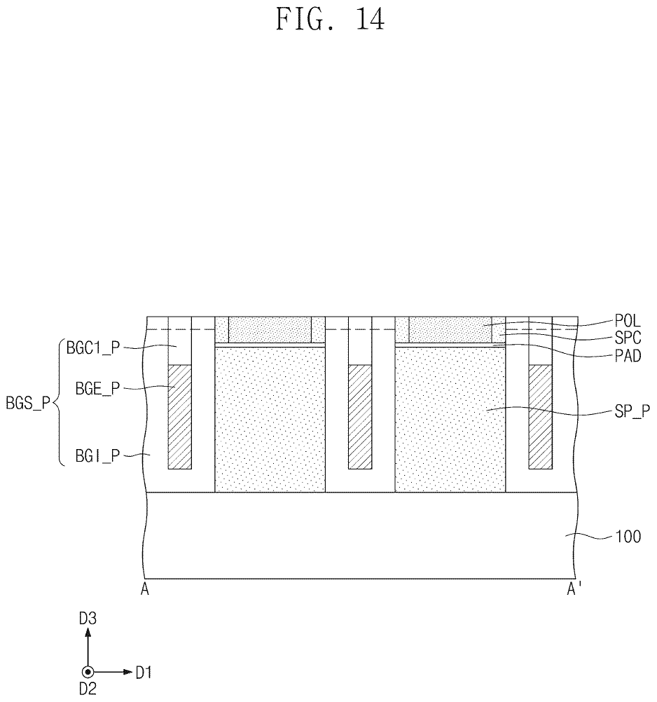

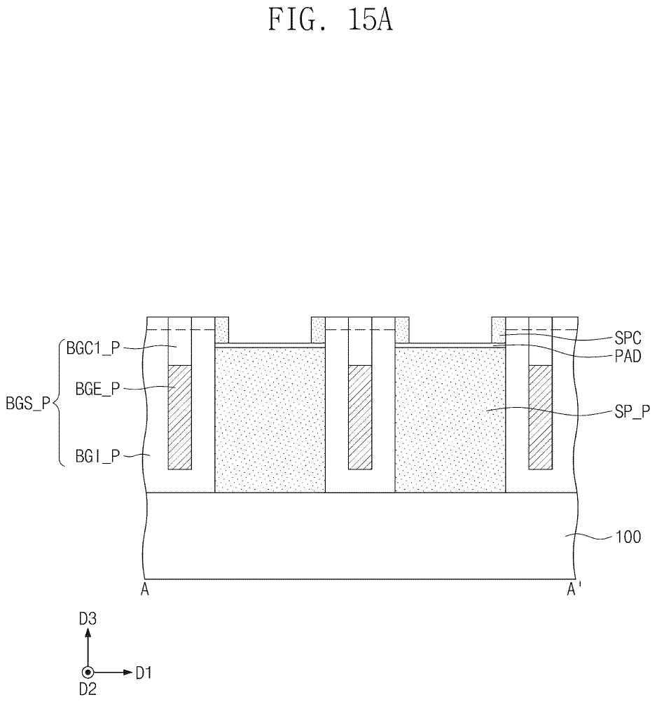

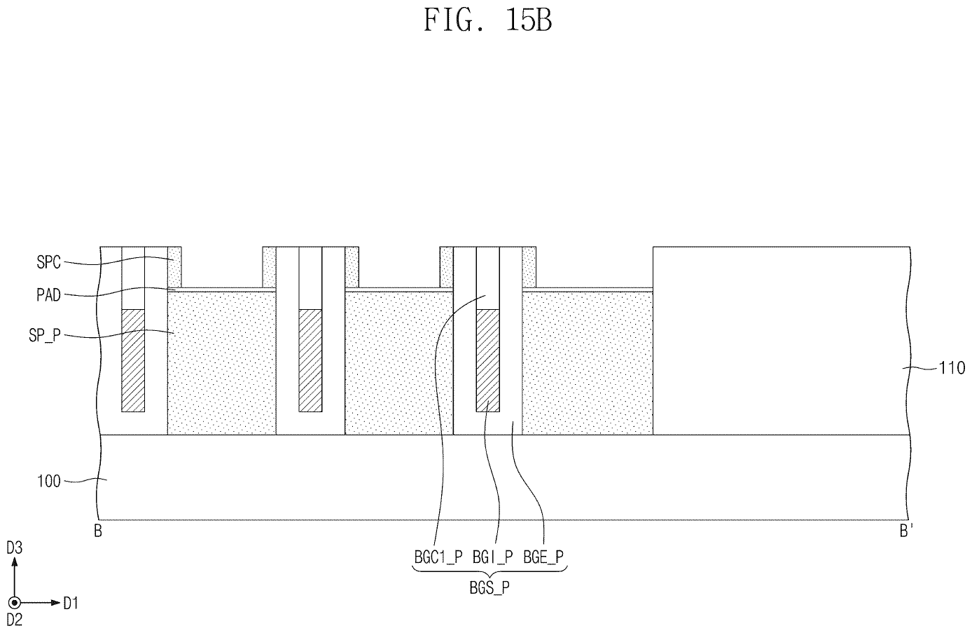

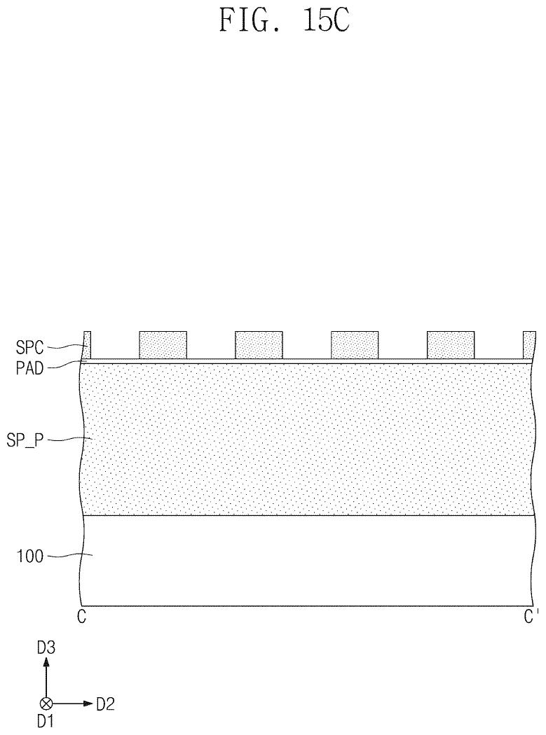

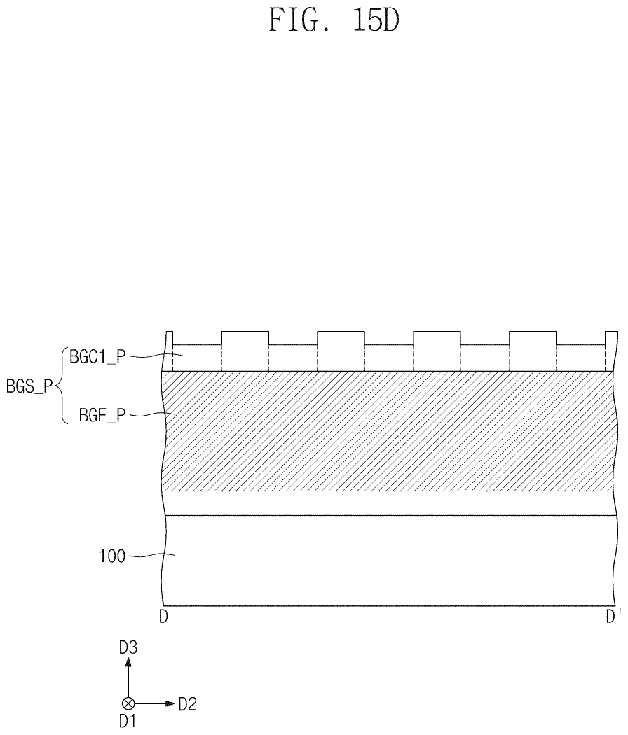

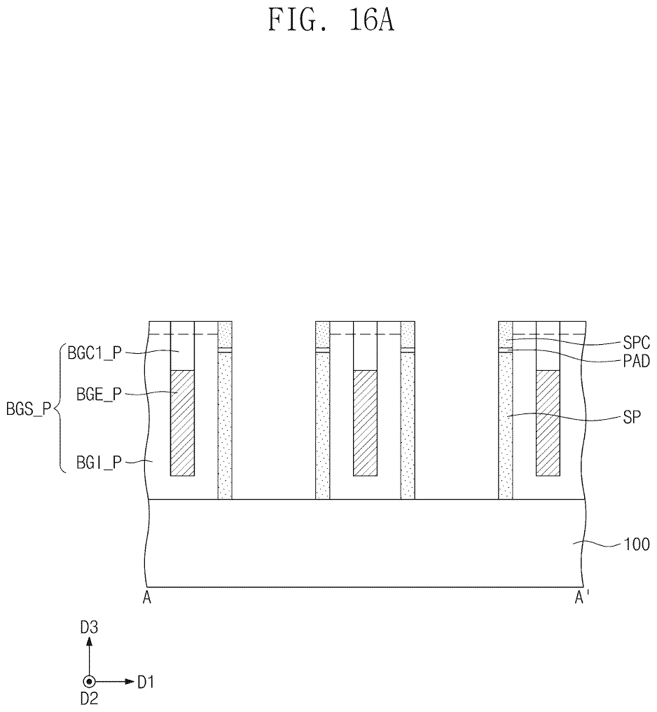

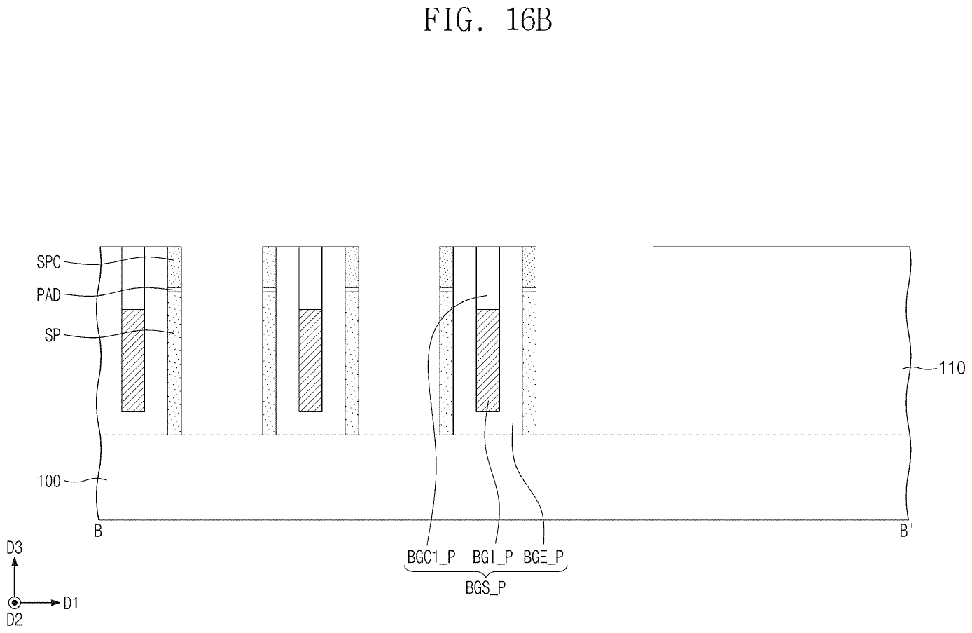

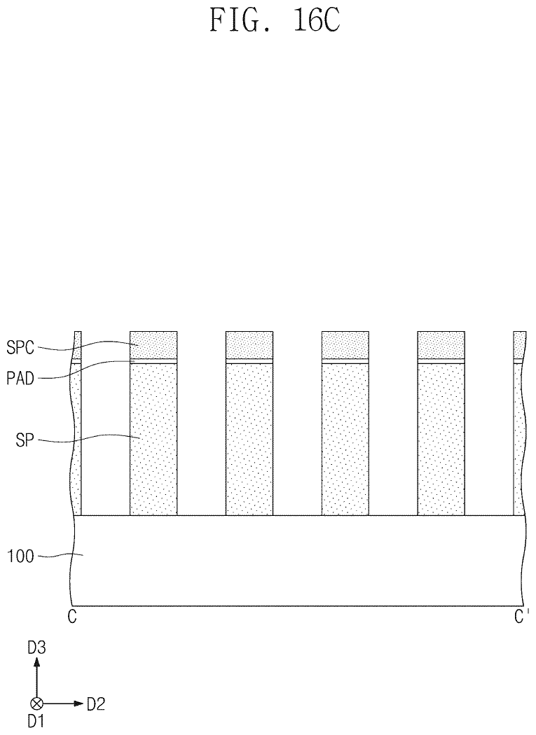

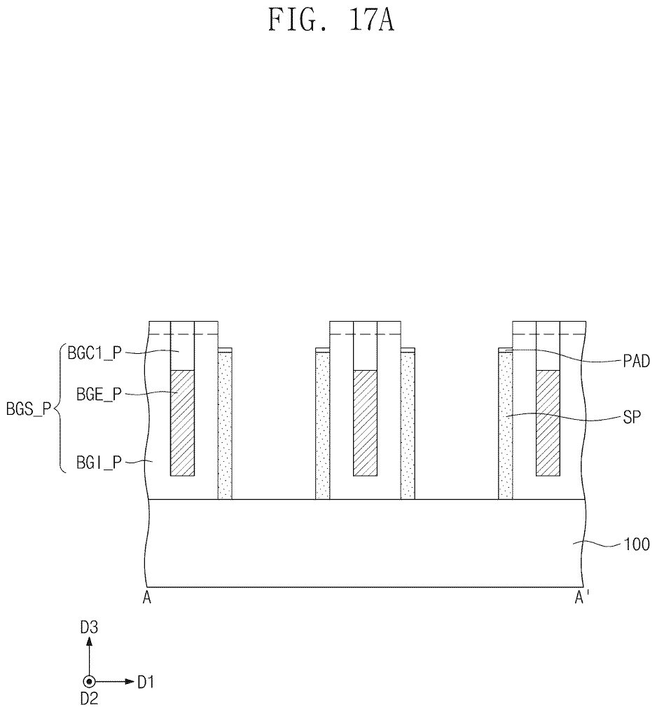

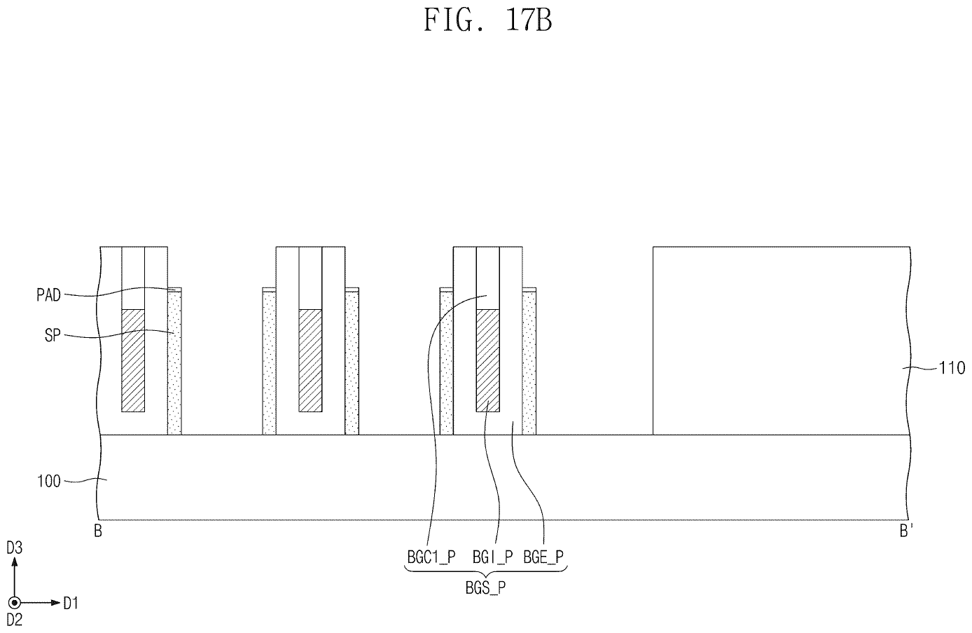

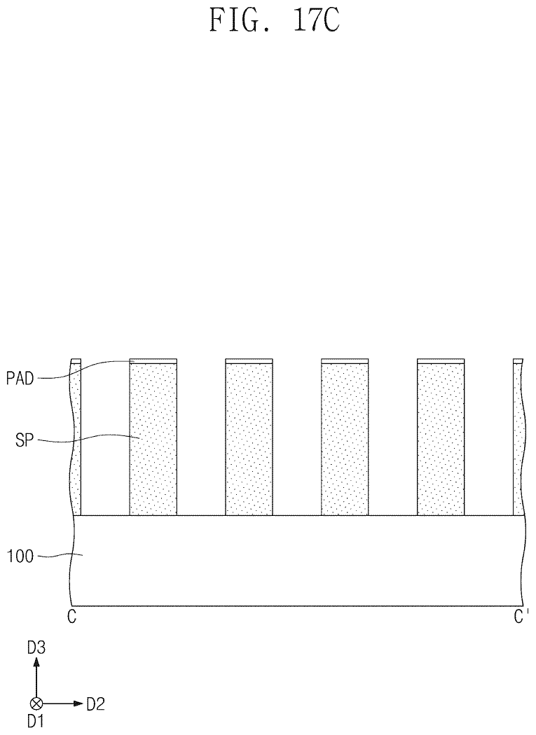

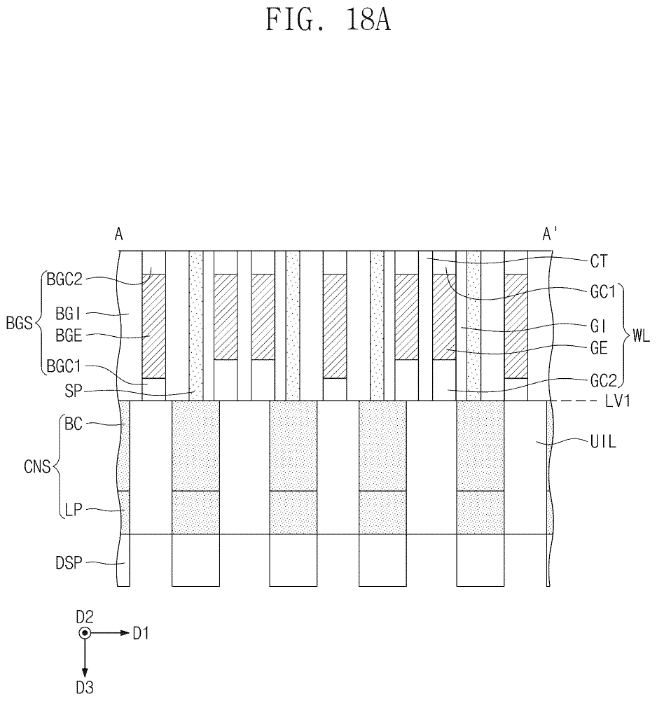

FIGS. 8A to 18C are diagrams illustrating an example of a method of manufacturing a semiconductor device. More specifically, FIG. 8A, FIG. 9A, FIG. 11A, FIG. 13A, FIG. 14, FIG. 15A, FIG. 16A, FIG. 17A, and FIG. 18A are cross-sectional views respectively taken along line A-A′ in FIG. 6. FIGS. 8B, 9B, 11B, 15B, 16B, 17B, and 18B are cross-sectional views respectively taken along line B-B′ in FIG. 6. FIGS. 9C, 11C, 13B, 15C, 16C, 17C, and 18C are cross-sectional views respectively taken along the line C-C′ of FIG. 6. FIGS. 9D, 11D, 13C, and 15D are cross-sectional views respectively taken along the line D-D′ of FIG. 6. FIGS. 10 and 12 are enlarged views of portion M of FIG. 5.

Referring to FIGS. 8A and 8B, a first substrate 100 may be prepared. A preliminary semiconductor pattern SP_P may be formed on the first substrate 100. As an example, the first substrate 100 and the preliminary semiconductor pattern SP_P may include a semiconductor material. A dummy insulating layer 110 adjacent to the preliminary semiconductor pattern SP_P in the first direction D1 may be formed on the first substrate 100 on the boundary region BR.

Then, by performing a patterning process on the preliminary semiconductor pattern SP_P, a first trench TR1 may be formed on the preliminary semiconductor patterns SP_P. The first trench TR1 may be formed to extend along the second direction D2. The preliminary semiconductor pattern SP_P may be separated into a plurality of preliminary semiconductor patterns SP_P by the first trench TR1.

A preliminary back gate structure BGS_P may be formed in the first trench TR1. For example, a preliminary back gate insulating pattern BGI_P may be formed to conformally cover the first trench TR1. A preliminary back gate electrode BGE_P may be formed to fill a lower portion of the first trench TR1 on the preliminary back gate insulating pattern BGI_P. A first preliminary back gate capping pattern BGC1_P may be formed to fill an upper portion of the first trench TR1 on the preliminary back gate electrode BGE_P.

Then, the height of the preliminary semiconductor patterns SP_P may be reduced by etching the upper portion of the preliminary semiconductor patterns SP_P. A top surface of the preliminary semiconductor patterns SP_P may be located at a lower level than a top surface of the preliminarily back gate insulating pattern BGI_P and a top surface of a first preliminary back gate capping pattern BGC1_P. A pad pattern PAD may be formed on the preliminary semiconductor pattern SP_P. The pad pattern PAD may be a thin insulating layer. The pad pattern PAD may include an insulating material. For example, the pad pattern PAD may include silicon oxide.

An etch spacer SPC may be formed on the pad pattern PAD. Forming the etch spacer SPC may include forming an etch spacer layer conformally on the pad pattern PAD, the preliminary back gate insulating pattern BGI_P, and the first preliminary back gate capping pattern BGC1_P. The etch spacer layer on the pad pattern PAD except for a portion on the side wall of the preliminary back gate insulating pattern BGI_P may be removed by an etch process. An etch-back process may be performed to remove the etch spacer layer on the top surface of the preliminary back gate insulating pattern BGI_P and on the top surface of a first preliminary back gate capping pattern BGC1_P. For this reason, in some implementations, the etch spacer SPC may be provided only on the side wall of the preliminary back gate insulating pattern BGI_P on the top surface of the pad pattern PAD.

The etch spacer SPC may include a material having an etching selectivity with respect to the first preliminary back gate capping pattern BGC1_P and a poly insulating layer POL. The etch spacer SPC may include a metal. For example, the etch spacer SPC may include TiN. For example, the etch spacer SPC may include at least one of titanium nitride, metal oxide, tungsten, polysilicon, doped silicon, silicon nitride, or silicon oxide.

The poly insulating layer POL may be formed on the substrate 100. The poly insulating layer POL may cover the pad pattern PAD, the preliminary back gate insulating pattern BGI_P, the first preliminary back gate capping pattern BGC1_P, and the etch spacer SPC.

Referring to FIGS. 9A to 9D, an etching process may be performed on the poly insulating layer POL. The etching process may be a chemical mechanical polishing (CMP) process. Therefore, the height of the poly insulating layer POL may be reduced. The poly insulating layer POL on the cell active region CR may be etched more than that on the boundary region BR. Since the boundary region BR is located at the edge of the cell active region CR, the poly insulating layer POL of the boundary region BR may be less etched. For this reason, the top surface of the poly insulating layer POL on the cell active region CR is located at a lower level than that on the boundary region BR, and a difference in height may occur.

While the poly insulating layer POL is etched, the preliminary back gate insulating pattern BGI_P and the first preliminary back gate capping pattern BGC1_P on the cell active region CR may also be etched together. Accordingly, the heights of the preliminary back gate insulating pattern BGI_P and the first preliminary back gate capping pattern BGC1_P may also be reduced, as shown in FIG. 9A. After the etching process, the top surface of the poly insulating layer POL on the cell active region CR may be coplanar with the top surface of the preliminary back gate insulating pattern BGI_P, the top surface the first preliminary back gate capping pattern BGC1_P, and a top surface of an etch spacer SPC.

On the other hand, as shown in FIG. 9B, the poly insulating layer POL on the boundary region BR may still cover the top surface of each of the preliminary back gate insulating pattern BGI_P, the first preliminary back gate capping pattern BGC1_P, and the etch spacer SPC. The height of each of the preliminary back gate insulating pattern BGI_P, the first preliminary back gate capping pattern BGC1_P, and the etch spacer SPC on the boundary region BR may not decrease. Therefore, the height of each of the preliminary back gate insulating pattern BGI_P, the first preliminary back gate capping pattern BGC1_P, and the etch spacer SPC may be greater on the boundary region BR than on the cell active region CR. That is, a first height HE1 of the preliminary back gate insulating pattern BGI_P of the cell active region CR may be smaller than a second height HE2 of the preliminary back gate insulating pattern BGI_P of the boundary region BR.

Referring to FIGS. 10 to 11D, first mask patterns MP may be formed on the poly insulating layer POL. On the cell active region CR, the first mask patterns MP may cover the poly insulating layer POL, the etch spacer SPC, the preliminary back gate insulating pattern BGI_P, and the first preliminary back gate capping pattern BGC1_P. The first mask patterns MP may extend in the first direction D1. The first mask patterns MP may be spaced apart from each other in the second direction D2. The first mask patterns MP may be formed on a region where a semiconductor pattern SP described later is formed. The first mask patterns MP may include a material having an etch selectivity with respect to each of the first preliminary back gate capping pattern BGC1_P, the etch spacer SPC, and the poly insulating layer POL. The etch selectivity for the first mask patterns MP may be different for each of the first preliminary back gate capping pattern BGC1_P, the etch spacer SPC, and the poly insulating layer POL.

Referring to FIGS. 12 to 13C, an etching process using the first mask patterns MP as a mask may be performed. By the etching process, the etch spacer SPC and the poly insulating layer POL exposed by the first mask patterns MP may be removed. An upper portion of the first preliminary back gate capping pattern BGC1_P exposed by the first mask patterns MP may also be etched. For this reason, the height of the exposed first preliminary back gate capping pattern BGC1_P may decrease from the first height H1 to the second height H2.

By the etching process, the etch spacer SPC may have a trapezoidal profile. A portion of the etch spacer SPC adjacent to the preliminary back gate insulating pattern BGI_P may remain without being etched. This is because the remaining portion is a portion adjacent to the preliminary back gate insulating pattern BGI_P and the first mask pattern MP, and thus may not be all removed. The remaining portion of the etch spacer SPC may decrease as it moves away from the preliminary back gate insulating pattern BGI_P. The etch spacer SPC may have the same profile as the semiconductor pattern SP of FIG. 6. For example, the etch spacer SPC may include outer walls and side walls substantially the same as the first and second outer walls OW1 and OW2 and the first and second side walls SW1 and SW2 of the semiconductor pattern SP of FIG. 6.

According to some implementations of the present disclosure, by using the etch spacer SPC, it is possible to prevent the exposed first preliminary back gate capping pattern BGC1_P from being excessively etched. This is because the etch spacer SPC includes a material having an etching selectivity not only for the first mask patterns MP but also for the first preliminary back gate capping pattern BGC1_P. Therefore, in the process for removing the etch spacer SPC exposed by the first mask pattern MP1 (see FIG. 13C), the preliminary back gate insulating pattern BGI_P and the first preliminary back gate capping pattern BGC1_P may be etched relatively little. Therefore, heights of each of the preliminary back gate insulating pattern BGI_P and the first preliminary back gate capping pattern BGC1_P can be sufficiently high. By sufficiently having the height of the first preliminary back gate capping pattern BGC1_P, the heights of the first back gate capping patterns BGC1 and the back gate electrode BGE can be adjusted. In addition, by sufficiently having the height of the first preliminary back gate capping pattern BGC1_P, it is possible to prevent the word lines WL adjacent to each other from contacting with each other beyond the first preliminary back gate capping pattern B GC1_P when the word line WL is formed.

Referring to FIG. 14, the first mask pattern MP may be removed. For this reason, the first preliminary back gate capping pattern BGC1_P, the preliminary back gate insulating pattern BGI_P, the etch spacer SPC, and the poly insulating layer POL may be exposed again. The dashed line indicates the height of the exposed first preliminary back gate capping pattern BGC1_P.

Referring to FIGS. 15A to 15D, an etching process may be performed to remove the poly insulating layer POL. For example, the etching process may be performed using ammonia water. By the etching process, the first preliminary back gate capping pattern BGC1_P, the preliminary back gate insulating pattern BGI_P, and the etch spacer SPC may not be removed.

By removing the poly insulating layer POL, the top surface of the pad pattern PAD may be exposed again. The poly insulating layer POL on the pad pattern PAD of the cell active region CR and the boundary region BR can be removed. The pad pattern PAD of each of the cell active region CR and the boundary region BR may be located at the same level as each other. In other words, the heights of the top surfaces of the preliminary semiconductor pattern SP_P of each of the cell active region CR and the boundary region BR may be located at substantially the same level (the first level LV1).

Referring to FIGS. 16A to 16C, an etching process using the etch spacer SPC as an etch mask may be performed to etch the pad pattern PAD and the preliminary semiconductor pattern SP_P. By the etching process, the preliminary semiconductor pattern SP_P may be etched to form the semiconductor patterns SP. The semiconductor patterns SP may be formed on side walls of the preliminary back gate insulating pattern BGI_P. The semiconductor patterns SP may be bar shapes extending in the third direction D3. By the etching process, an upper portion of each of the first preliminary back gate capping pattern BGC1_P and the preliminary back gate insulating pattern BGI_P may be etched. For this reason, the height of each of the first preliminary back gate capping pattern BGC1_P and the preliminary back gate insulating pattern BGI_P may be reduced.

Referring to FIGS. 17A to 17C, an etching process may be performed to remove the etch spacer SPC. The etching process may be a wet etching process. By the etching process, the etch spacer SPC may be removed selectively, and the semiconductor pattern SP may not be removed by the pad pattern PAD. That is, the pad pattern PAD can prevent the semiconductor pattern SP from being removed.

By removing the etch spacer SPC, the height of the semiconductor patterns SP of each of the cell active region CR and the boundary region BR may be substantially the same. Therefore, the top surfaces of the semiconductor patterns SP of each of the cell active region CR and the boundary region BR may be located at the same level as each other.

Referring to FIGS. 18A to 18C, a word line WL may be formed between the semiconductor patterns SP. Forming the word line WL may include forming a gate insulating pattern GI covering a side wall of the semiconductor pattern SP, and sequentially forming a second gate capping pattern GC2, a gate electrode GE, and a first gate capping pattern GC1 on the gate insulating pattern GI. Thereafter, a cutting pattern CT penetrating through the gate electrode GE may be formed.

A storage node contact BC and a landing pad LP may be sequentially formed on the semiconductor pattern SP. An upper insulating layer UIL surrounding each of the storage node contact BC and the landing pad LP may be formed. The upper insulating layer UIL may be formed at various times regardless of before or after formation of the storage node contact BC and the landing pad LP. Then, a data storage pattern DSP may be formed on the landing pad LP.

Thereafter, the top and bottom surfaces of the first substrate 100 may be inverted to expose the bottom surface of the first substrate 100. The first substrate 100 may be removed until the bottom surface of the first preliminary back gate insulating pattern BGI_P is exposed. An etching process may be performed on the first preliminary back gate insulating pattern BGI_P to etch the bottom surface of the back gate electrode BGE and fill the insulating material to form the second back gate capping pattern BGC2.

Referring again to FIGS. 7A to 7D, a bit line contact DC may be formed on a bottom surface of the semiconductor pattern SP. A bit line BL may be formed on the bit line contact DC. The lower insulating layer LIL may be formed to cover the bit line contact DC and the bit line BL. The lower insulating layer LIL may be formed at any of various times in the fabrication process, regardless of before or after formation of the bit line contact DC and the bit line BL.

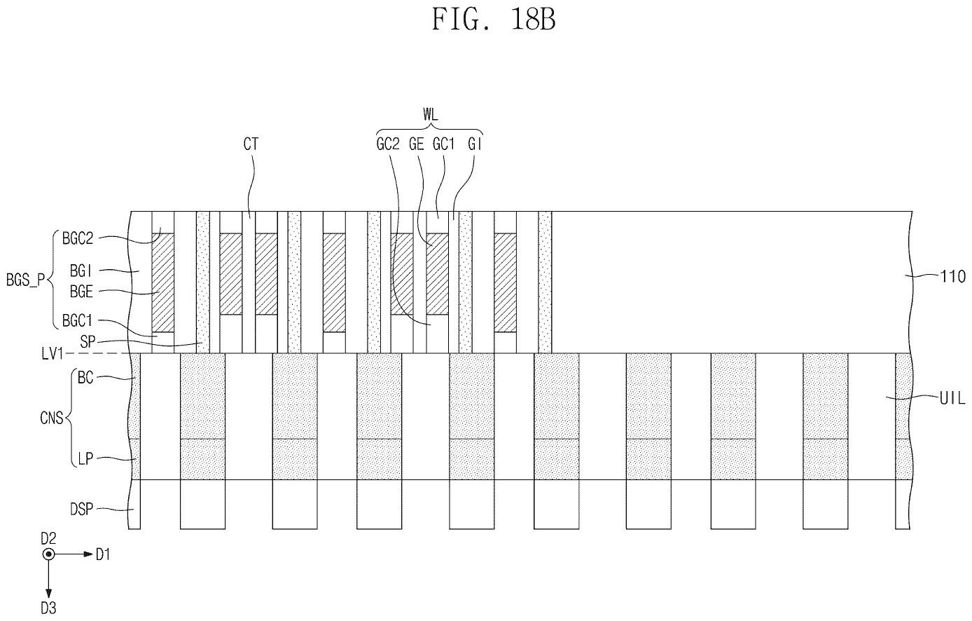

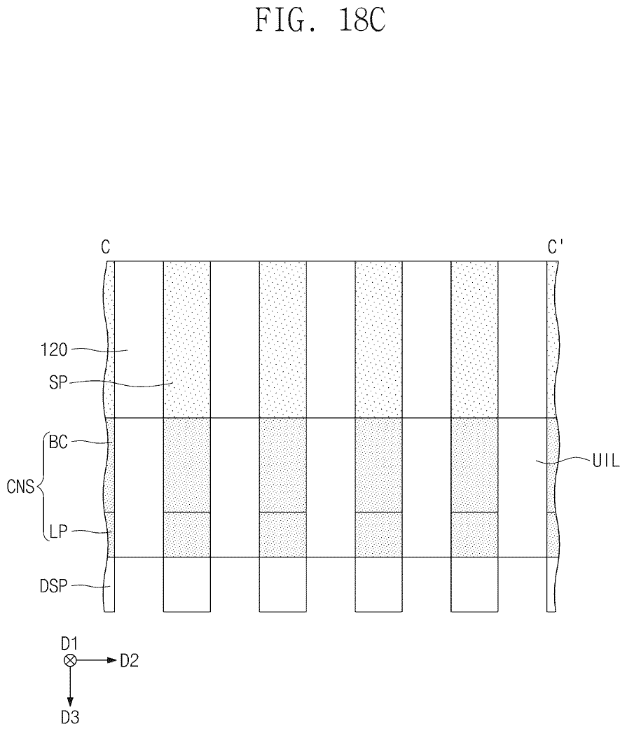

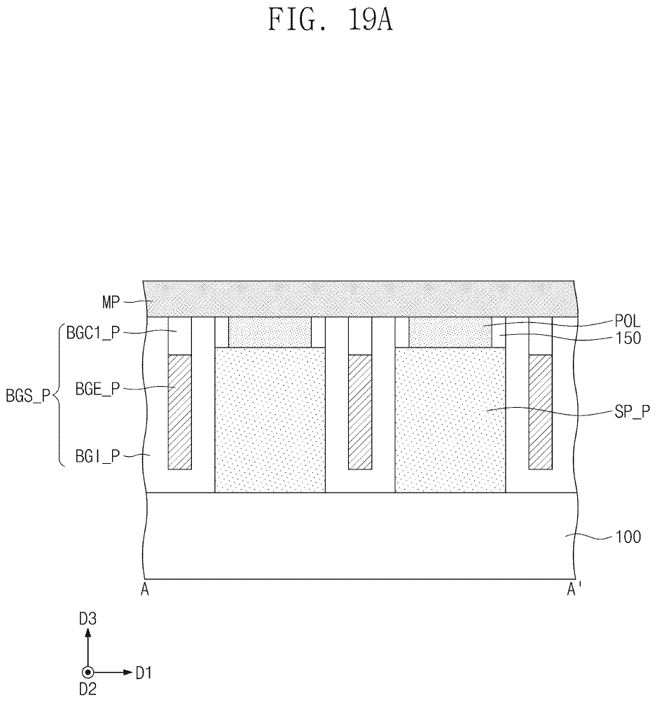

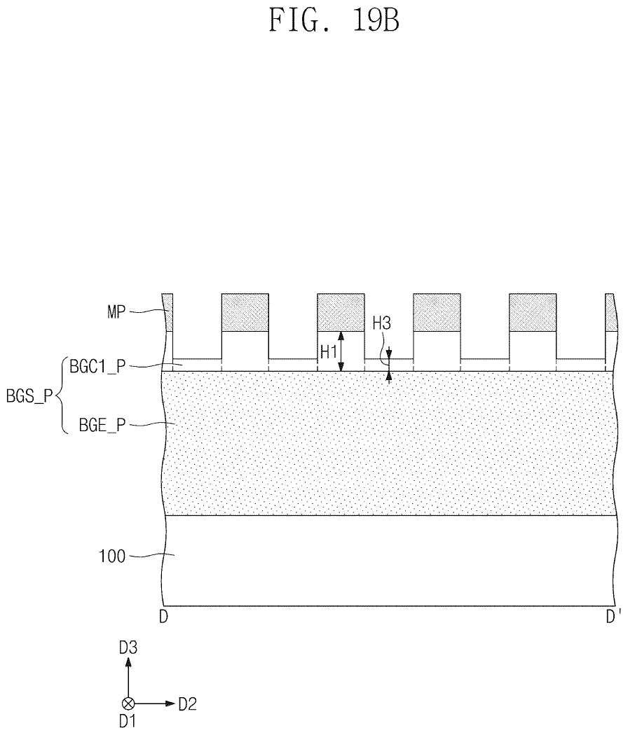

FIGS. 19A and 19B are diagrams illustrating a method of manufacturing a semiconductor device in the absence of an etch spacer SPC. FIGS. 19A and 19B correspond to FIGS. 13A and 13C, respectively. For simplicity of description, description of content overlapping with the above-described content will be omitted, and differences from the above-described contents will be mainly described.

Referring to FIGS. 19A and 19B, the etch spacer SPC is omitted, and an oxidation spacer 150 may be provided. The oxidation spacer 150 may include a material having no etch selectivity with respect to the preliminary back gate insulating pattern BGI_P. For example, the oxidation spacer 150 may include the same material as the preliminary back gate insulating pattern BGI_P. For example, the oxidation spacer 150 may include silicon oxide. In addition, the pad pattern PAD may be omitted on the preliminary semiconductor pattern SP_P.

An etching process may be performed using the first mask pattern MP as an etch mask. By the etching process, the oxidation spacer 150 exposed by the first mask pattern MP may be removed. Since the oxidation spacer 150 includes a material having no etch selectivity with respect to the preliminary back gate insulating pattern BGI_P, the preliminary back gate insulation pattern BGI_ P and the first preliminary back gate capping pattern BGC1_P may be etched together. Therefore, unlike FIG. 13C, the preliminary back gate insulating pattern BGI_P exposed by the first mask pattern MP may be etched relatively more in comparison to FIG. 13C. Therefore, the height of the exposed preliminary back gate insulating pattern BGI_P after the etching process can be greatly reduced from the first height H1 to a third height H3. Consequently, the height of each of the preliminary back gate insulating pattern BGI_P and the first preliminary back gate capping pattern BGC1_P may not be sufficiently high. For this reason, when the word lines WL are formed, there may be a problem that adjacent word lines WL contact with each other or a problem that the height of the back gate electrode BGE is not sufficiently high.

In addition, the pad pattern PAD is omitted, so that the heights of the first back gate capping pattern BGC1 and the semiconductor patterns SP on the cell active region CR and the boundary region BR are different from each other, thereby forming a difference in height. As a result, the reliability and electrical characteristics of the semiconductor device may be weakened.

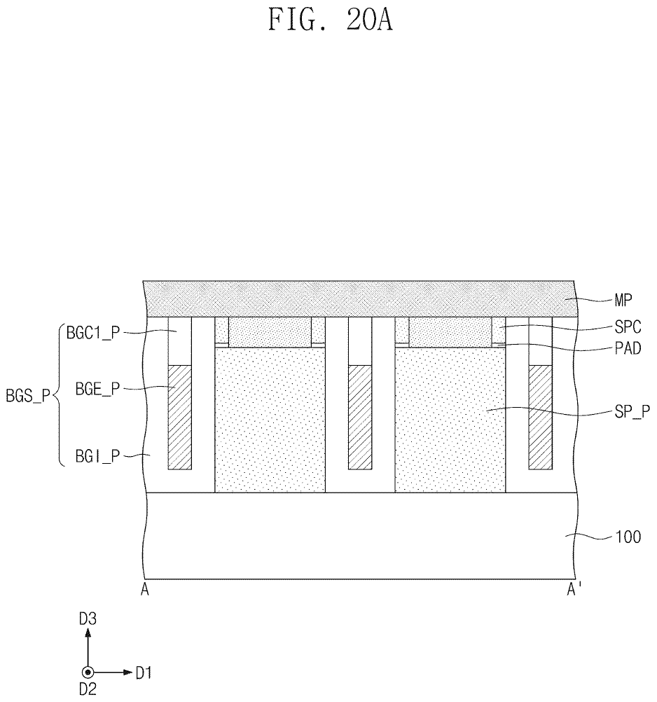

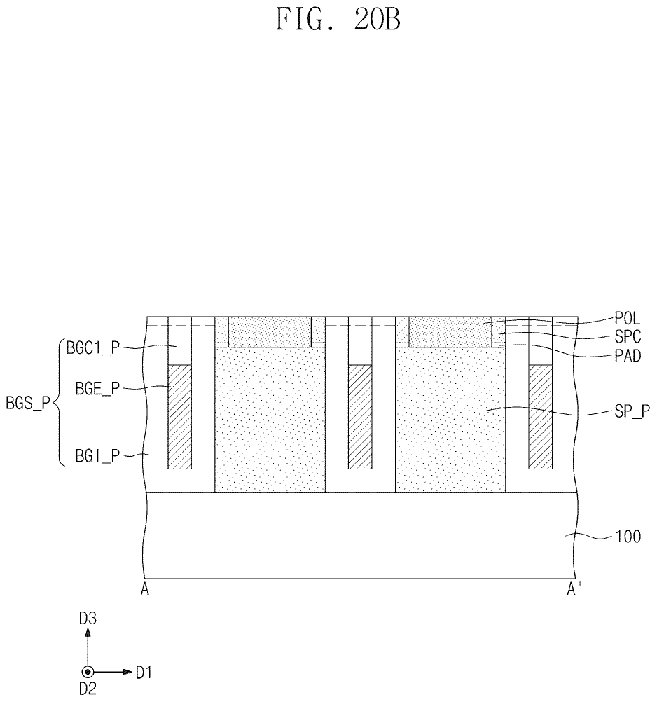

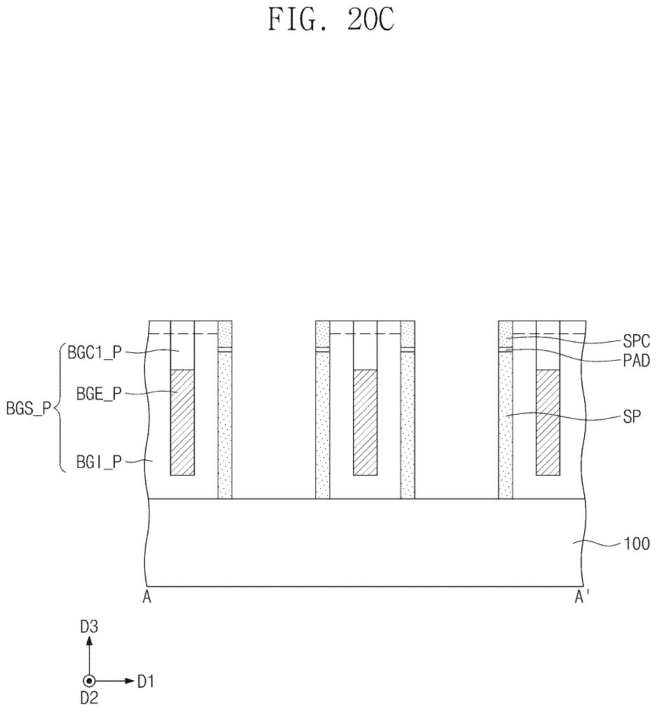

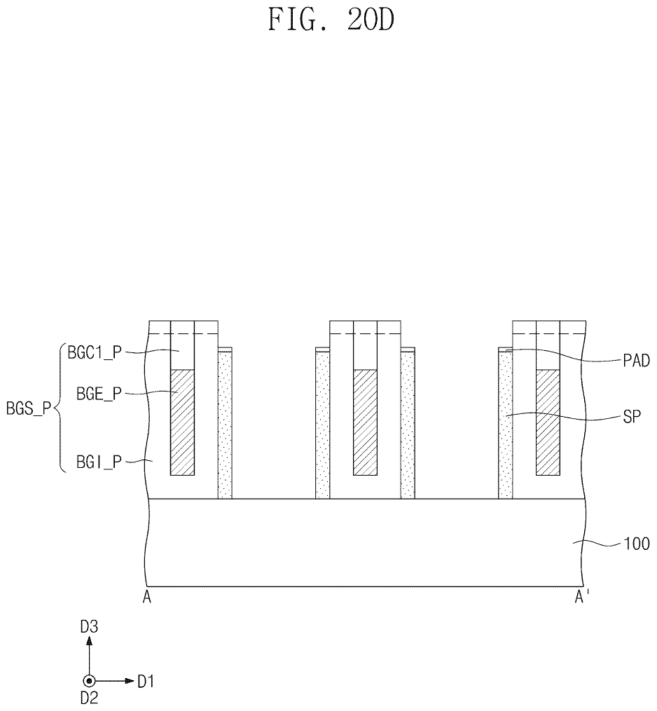

FIGS. 20A to 20D are diagrams illustrating another example of a method of manufacturing a semiconductor device. For simplicity of description, description of content overlapping with the above-described content will be omitted, and differences from the above-described contents will be mainly described.

FIGS. 20A and 20B correspond to FIGS. 13A and 14, respectively. Referring to FIG. 20A, the pad pattern PAD may be omitted between the preliminary semiconductor pattern SP_P and the poly insulating layer POL. The pad pattern PAD and an etch spacer SPC may be formed on the preliminary semiconductor pattern SP_P, and then the pad pattern PAD exposed by the etch spacer SPC may be etched. The poly insulating layer POL may be formed on the top surface of the preliminary semiconductor pattern SP_P from which the pad pattern PAD is removed. Therefore, the pad pattern PAD may be formed only between the preliminary semiconductor pattern SP_P and the etch spacer SPC.

Referring to FIG. 20B, the first mask pattern MP may be removed, and the poly insulating layer POL, the etch spacer SPC, the preliminary back gate insulating pattern BGI_P, and the first preliminary back gate capping pattern BGC1_P may be exposed.

Referring to FIG. 20C, an etching process using the etch spacer SPC as a mask may be performed to remove a portion of the poly insulating layer POL and the preliminary semiconductor pattern SP_P at once. For example, all of the poly insulating layers POL may be removed by the etching process, and the preliminary semiconductor pattern SP_P exposed by the etch spacer SPC may also be removed. Accordingly, removing the poly insulating layer POL and forming the semiconductor pattern SP by the etching process may be performed at once. This may be possible because the pad pattern PAD is omitted between the poly insulating layer POL and the preliminary semiconductor pattern SP_P. In addition, relatively little of the etch spacer SPC adjacent to the preliminary back gate insulating pattern BGI_P may remain. Accordingly, the first angle θ1 of FIG. 6 may increase relatively.

Referring to FIG. 20D, the etch spacer SPC may be removed. Removing the etch spacer SPC may be substantially the same as described with reference to FIGS. 17A to 17C.

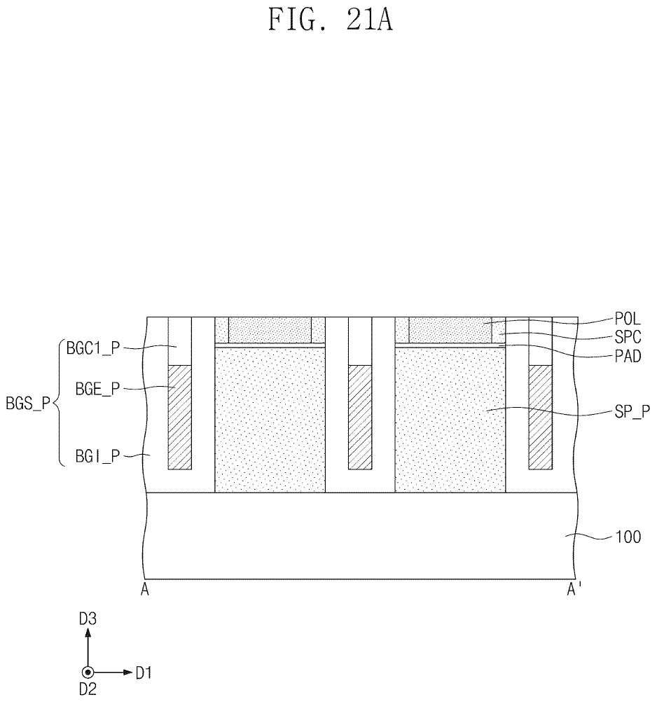

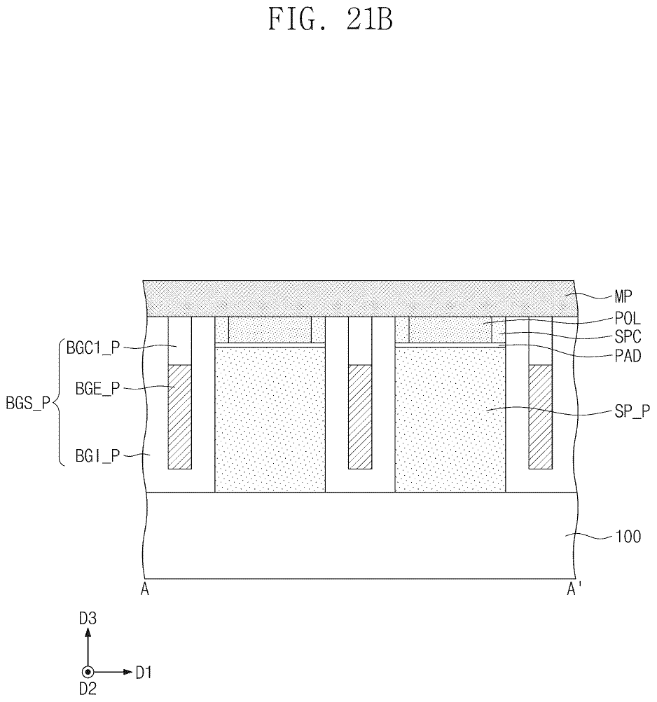

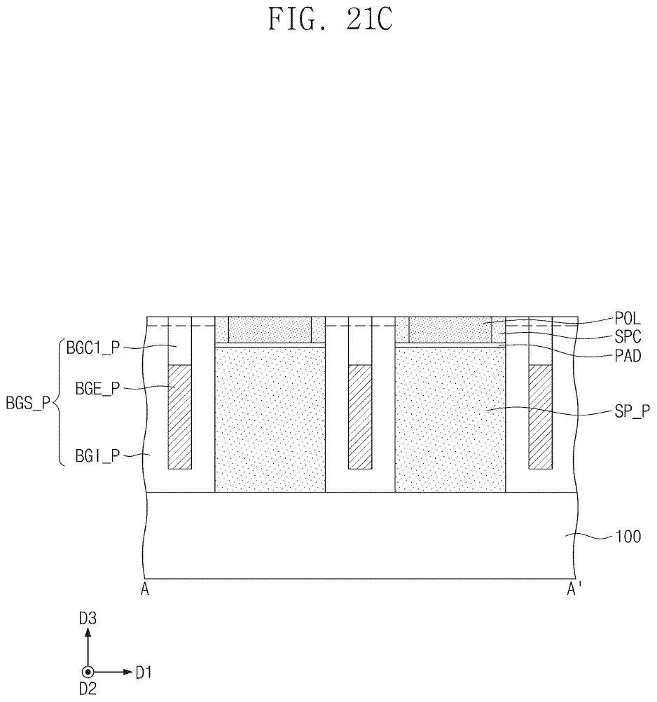

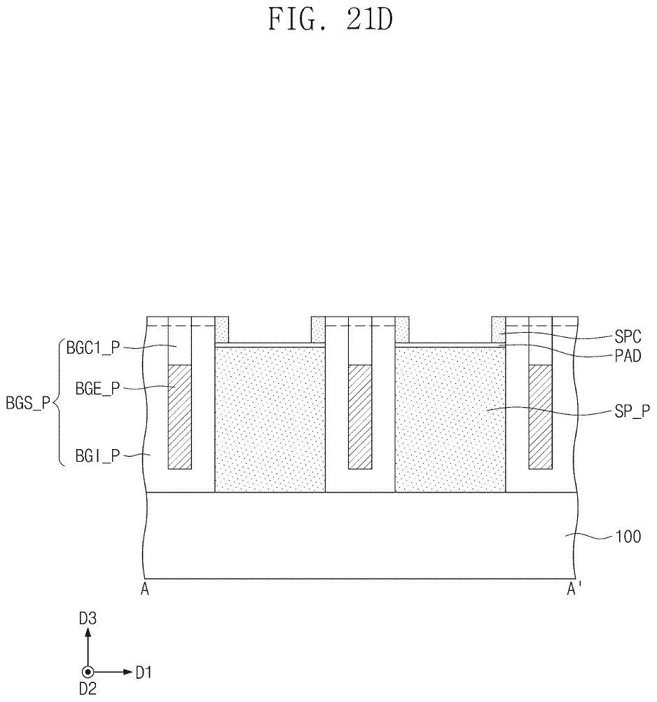

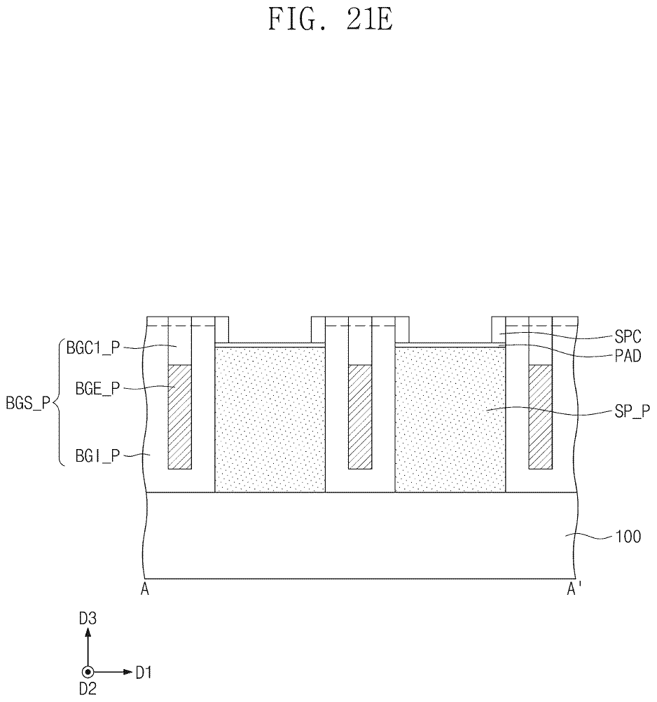

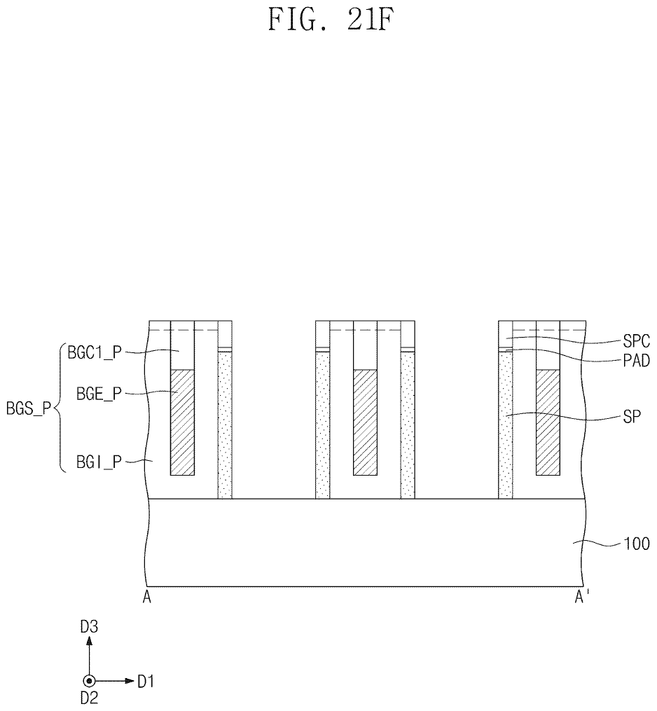

FIGS. 21A to 21F are diagrams illustrating another example of a method of manufacturing a semiconductor device. For simplicity of description, description of content overlapping with the above-described content will be omitted, and differences from the above-described contents will be mainly described.

Referring to FIG. 21A, materials of the poly insulating layer POL and the etch spacer SPC may be interchanged with each other. The poly insulating layer POL may include a material having an etch selectivity with respect to the first preliminary back gate capping pattern BGC1_P and the poly insulating layer POL. The poly insulating layer POL may include a metal. For example, the poly insulating layer POL may include at least any one of titanium nitride, metal oxide, tungsten, polysilicon, doped silicon, silicon nitride, or silicon oxide. On the other hand, the etch spacer SPC may include an insulating material. For example, the etch spacer SPC may include polysilicon. However, the poly insulating layer POL and the etch spacer SPC may still include a material having an etching selectivity with respect to each other.

Referring to FIG. 21B, the first mask pattern MP may cover the poly insulating layer POL, the etch spacer SPC, the preliminary back gate insulating pattern BGI_P, and the first preliminary back gate capping pattern BGC1_P. The first mask pattern MP of FIG. 21B may be substantially the same as the first mask pattern MP described with reference to FIGS. 10 to 11D. The first mask pattern MP may include a material having an etching selectivity with respect to the poly insulating layer POL, the etch spacer SPC, and the preliminary back gate insulating pattern BGI_P.

Referring to FIG. 21C, an etching process may be performed using the first mask pattern MP as a mask. The etching process of FIG. 21 may be substantially the same as the etching process described with reference to FIGS. 12-13C. Thereafter, the first mask pattern MP may be removed.

Referring to FIG. 21D, the poly insulating layer POL exposed after being removed from the first mask pattern MP may be removed. In this case, the pad pattern PAD may be used as an etch stop layer. In addition, the etch spacer SPC may not be removed.

Referring to FIG. 21E, an oxidation process may be performed on the exposed etch spacer SPC. The oxidation process may be performed on both side walls and the top surface of the etch spacer SPC. For this reason, the etch spacer SPC may include a material having no etching selectivity with respect to the preliminary back gate insulating pattern BGI_P and the first preliminary back gate capping pattern BGC1_P.

Referring to FIG. 21F, an etching process may be performed using the oxidized etch spacer SPC as a mask to etch a portion of the preliminary semiconductor pattern SP_P to form the semiconductor pattern SP. By the etching process, the preliminary back gate insulating pattern BGI_P and the first preliminary back gate capping pattern BGC1_P may not be removed, so that the respective heights may still be maintained high. The subsequent process may be substantially the same as that described with reference to FIGS. 17A to 18C.

Based on implementations of the above description, an etch spacer adjacent to a back gate insulating pattern can be used to form a semiconductor pattern. The etch spacer may include a material having an etch selectivity for each of the back gate insulating pattern and the poly insulating layer. The height of the back gate capping pattern on the top surface of the back gate electrode can thereby be kept high to prevent adjacent gate electrodes from contacting with each other. Further, the angle between the first outer wall and the first side wall adjacent to the back gate electrode of the semiconductor pattern may be in range from 40° to 80°. The width of the first outer wall of the semiconductor pattern may be greater than the width of the second outer wall adjacent to the gate electrode. Further, the top surface of each of the semiconductor patterns on the cell active region and the boundary region may be at the same level. There may be no difference in height in the semiconductor patterns on the cell active region and the boundary region. As a result, the heights of the back gate electrodes can be increased and the reliability of the semiconductor device can be improved.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to examples thereof, it will be apparent to those of ordinary skill in the art that various changes and modifications may be made thereto without departing from the spirit and scope of the present disclosure as set forth in the following claims.

What is claimed is:

1. A semiconductor device, comprising:
a substrate including a cell active region and a boundary region;
a bit line extending along a first direction parallel to a top surface of the substrate;
a semiconductor pattern extending along a direction perpendicular to the top surface of the substrate, wherein the semiconductor pattern is disposed on the bit line;
a back gate electrode extending along a second direction parallel to the top surface of the substrate, wherein the second direction intersects the first direction; and
a gate electrode spaced apart from the back gate electrode in the first direction, wherein the semiconductor pattern is between the gate electrode and the back gate electrode in the first direction,
wherein the semiconductor pattern comprises:
a first outer wall extending in the second direction,
a second outer wall opposing the first outer wall in the first direction, wherein, in the first direction, the first outer wall is closer than the second outer wall to the back gate electrode, and
a first side wall connecting the first outer wall and the second outer wall, and
wherein an angle between the first side wall and the first outer wall is in a range from 40° to 80°.

2. The semiconductor device of claim 1, wherein a length of the first outer wall in the second direction is greater than a length of the second outer wall in the second direction.

3. The semiconductor device of claim 1, wherein an angle between the first side wall and the second outer wall is in a range from 100° to 140°.

4. The semiconductor device of claim 1, comprising a gate insulating pattern between the semiconductor pattern and the gate electrode,
wherein, in the first direction, the second outer wall is closer than the first outer wall to the gate electrode, and
wherein the gate insulating pattern is in contact with the first side wall and the second outer wall.

5. The semiconductor device of claim 1, comprising a back gate insulating pattern between the semiconductor pattern and the back gate electrode,
wherein the first outer wall is in contact with the back gate insulating pattern.

6. The semiconductor device of claim 1, wherein a ratio of a greatest width of the semiconductor pattern in the first direction to a length of the second outer wall is in a range from 0.5 to 0.8.

7. The semiconductor device of claim 1, wherein a greatest width of the semiconductor pattern in the second direction is a same as a length of the first outer wall, and
wherein a width of the semiconductor pattern in the second direction decreases as a distance from the first outer wall increases.

8. The semiconductor device of claim 1, wherein the first side wall comprises a concave surface curving toward an inside of the semiconductor pattern.

9. The semiconductor device of claim 1, wherein the cell active region includes a memory cell,
wherein the boundary region comprises circuitry connecting a sense amplifier or a row decoder with the cell active region, and
wherein a top surface of the semiconductor pattern on the cell active region is at a same level as a top surface of the semiconductor pattern on the boundary region.

10. The semiconductor device of claim 1, comprising a first back gate capping pattern on a top surface of the back gate electrode,
wherein a height of the first back gate capping pattern is in a range from 150 Å to 200 Å.

11. A semiconductor device, comprising:
a substrate including a cell active region and a boundary region;
a bit line extending along a first direction parallel to a top surface of the substrate;
a semiconductor pattern extending along a direction perpendicular to the top surface of the substrate, wherein the semiconductor pattern is disposed on the bit line;
a back gate electrode extending along a second direction parallel to the top surface of the substrate, wherein the second direction intersects the first direction; and
a gate electrode spaced apart from the back gate electrode in the first direction, wherein the semiconductor pattern is between the gate electrode and the back gate electrode in the first direction,
wherein the cell active region includes a memory cell,
wherein the boundary region surrounds the cell active region and comprises circuitry connecting the cell active region with a sense amplifier, and
wherein a top surface of the semiconductor pattern on the cell active region is at a same level as a top surface of the semiconductor pattern on the boundary region.

12. The semiconductor device of claim 11, comprising a first back gate capping pattern on a top surface of the back gate electrode,
wherein a height of the first back gate capping pattern is in a range from 150 Å to 200 Å.

13. The semiconductor device of claim 12, wherein a top surface of the first back gate capping pattern on the cell active region is at a same level as a top surface of the first back gate capping pattern on the boundary region.

14. The semiconductor device of claim 11, comprising a first gate capping pattern on a top surface of the gate electrode,
wherein a height of the first gate capping pattern is in a range from 200 Å to 300 Å.

15. The semiconductor device of claim 11, wherein the semiconductor pattern has a hemispherical profile in a plan view.

16. The semiconductor device of claim 11, wherein a height of the semiconductor pattern on the cell active region is a same as a height of the semiconductor pattern on the boundary region.

17. A semiconductor device, comprising:
a substrate including a cell active region and a boundary region;
a bit line extending along a first direction parallel to a top surface of the substrate;
a semiconductor pattern extending along a direction perpendicular to the top surface of the substrate, wherein the semiconductor pattern is disposed on the bit line;
a back gate electrode extending along a second direction parallel to the top surface of the substrate, wherein the second direction intersects the first direction;
a gate electrode spaced apart from the back gate electrode in the first direction, wherein the semiconductor pattern is between the gate electrode and the back gate electrode in the first direction;
a gate insulating pattern between the semiconductor pattern and the gate electrode; and
a back gate insulating pattern between the semiconductor pattern and the back gate electrode,
wherein the semiconductor pattern comprises:
a first outer wall extending in the second direction,
a second outer wall opposing the first outer wall in the first direction, wherein, in the first direction, the first outer wall is closer than the second outer wall to the back gate electrode, and
a first side wall connecting the first outer wall and the second outer wall,
wherein a length of the first outer wall is greater than a length of the second outer wall, and
wherein a ratio of a greatest width of the semiconductor pattern in the first direction to a length of the second outer wall is in a range from 0.5 to 0.8.

18. The semiconductor device of claim 17, wherein a greatest width of the semiconductor pattern in the second direction is a same as a length of the first outer wall, and
wherein a width of the semiconductor pattern in the second direction decreases as a distance from the first outer wall increases.

19. The semiconductor device of claim 17, wherein the first side wall comprises a concave surface curved toward an inside of the semiconductor pattern.

20. The semiconductor device of claim 17, wherein a ratio of a length of the first outer wall in the second direction to a length of the second outer wall in the second direction is in a range from 1.4 to 1.7.
